(19) United States
(12) Patent Application Publication
(10) Pub. No.: US 2026/0154192 A1
(43) Pub. Date: Jun. 4, 2026

(54) IN-MEMORY SEARCHING IN NOR FLASH MEMORY USING EUCLIDEAN (L2) DISTANCE COMPUTING

(71) Applicant: MACRONIX INTERNATIONAL CO., LTD., HSINCHU (TW)

(72) Inventors: Yu-Hsuan LIN, TAICHUNG (TW); Po-Hao TSENG, TAICHUNG (TW); Feng-Min LEE, HSINCHU (TW); Yu-Yu LIN, New Taipei City (TW)

(73) Assignee: MACRONIX INTERNATIONAL CO., LTD., HSINCHU (TW)

(21) Appl. No.: 18/964,183

(22) Filed: Nov. 29, 2024

(51) Int. Cl. G06F 12/02; G11C 15/04; G11C 16/04; G11C 16/10

(52) U.S. Cl. CPC G06F 12/0246; G11C 15/046; G11C 16/0425; G11C 16/10

(57) ABSTRACT

A memory system is provided to include a memory device configured to store data for searching, and a memory controller configured with logic to (i) program the memory device, according to programming voltages, to store storage data, (ii) provide search voltages to the memory device in dependence on input data and (iii) determine a level of similarity between the stored storage data and the input data according to an output current from the memory device that represents a Euclidean distance between the stored storage data and the input data. The computing system further includes configuration circuitry including logic to determine a base threshold voltage (Vt) according to which the memory controller (i) programs the memory device and (ii) provides the one or more search voltages, wherein the base threshold voltage (Vt) is determined, such that the output current represents the Euclidean distance between the storage data and the input data.

### BACKGROUND

### Field

This disclosure relates to in-memory searching (IMS) using, for example, flash memory. More specifically, this disclosure relates to IMS that determines a difference between a stored logical value (e.g., stored data) and an input logical value (e.g., input data) using Euclidean distance computing to determine how similar or dissimilar the input value is to the stored value.

### Description of Related Art

Growth of big data and artificial intelligence (AI), such as AI hardware accelerators, are increasing the importance of searching, comparing, and/or sorting data (e.g., in-memory searching (IMS)). Conventional systems that perform IMS can implement searching using ternary content addressable memory (TCAM) technology or other techniques that indicate whether there is a match between stored data and input data.

For example, conventional TCAM can be technology that is implementable using static randomly accessible memory (SRAM) techniques, and using non-volatile memory techniques, such as based on two transistor two resistor (2T2R) techniques and two ferroelectric field-effect transistor (2FeFET) techniques. Conventionally, this TCAM searching only indicates whether there is a match between stored data and input data or a mismatch between the stored data and the input data. Additionally, for example, conventional IMS can be performed using NAND-flash-based memory. However, these conventional NAND-flash-based memory techniques also only indicate whether there is a match between stored data and input data or a mismatch between the stored data and the input data.

Certain applications of IMS would benefit from being able to determine how similar or dissimilar input data is from stored data. In other words, it would be beneficial to know how close the input data is to the stored data if there is a mismatch. Therefore, in addition to being able to perform an IMS that indicates whether input data is a match or a mismatch with respect to stored data, a need arises for IMS techniques that indicate how similar or dissimilar input data is to stored data when there is a mismatch.

### SUMMARY

In an embodiment, a memory system is provided, the memory system including a memory device configured to store data for in-memory searching, a memory controller configured with logic to (i) program the memory device, according to one or more programming voltages, to store storage data, (ii) provide one or more search voltages to the memory device in dependence on input data and (iii) determine a level of similarity between the stored storage data and the input data according to an output current from the memory device that represents a Euclidean distance between a stored logical value represented by the stored storage data and an input logical value represented by the input data, and configuration circuitry including logic to determine a base threshold voltage (Vt) according to which the memory controller (i) programs the memory device using the one or more programming voltages to set one or more threshold voltages and (ii) provides the one or more search voltages, wherein the base threshold voltage (Vt) is determined, such that the output current represents the Euclidean distance between the stored logical value represented by the storage data and the input logical value represented by the input data.

In an embodiment, the base threshold voltage (Vt) is determined in dependence on an ideal base threshold voltage Vt that is calculated by extrapolating a line with respect to known or determined characteristics of the memory device that are represented by a √Id vs gate voltage (Vg) curve, where Id is a drain current provided by a memory device in response to the gate voltage (Vg).

In another embodiment, the logic to determine the base threshold voltage (Vt) further includes calculating a partial derivative curve from the known or determined characteristics of the memory device that are represented by the \sqrt{Id} vs gate voltage (Vg) curve, and identifying, as the ideal base threshold voltage Vt, a value of the gate voltage (Vg) determined in dependence on a peak point of the calculated partial derivative curve and a line that is tangent to a determined point on the \sqrt{Id} vs gate voltage (Vg) curve that corresponds to the peak point, wherein the base threshold voltage (Vt) is set in dependence on the calculated ideal base threshold voltage Vt.

In a further embodiment, the logic to determine the base threshold voltage (Vt) further includes determining a Vg peak value, which is a voltage that aligns with the peak point of the calculated partial derivative curve, determining the point on the \sqrt{Id} vs gate voltage (Vg) curve that aligns with the determined Vg peak value, calculating the line that is tangent to the determined point on the \sqrt{Id} vs gate voltage (Vg) curve to have a slope defined by the peak point of the calculated partial derivative curve, and determining the ideal base threshold voltage Vt value to correspond to a point on the calculated line where \sqrt{Id}=0.

In an embodiment, the base threshold voltage (Vt) can be determined in dependence on an extracted base threshold voltage Vt that is calculated by applying the ideal base threshold voltage Vt to a group of memory cells within the memory device.

In another embodiment, the extracted base threshold voltage Vt can be determined by determining an actual median drain current Id at the calculated ideal base threshold voltage Vt for a group of memory cells within the memory device and defining the median drain current Id as current Ith, and determining the extracted base threshold voltage Vt from the known drain current Id vs gate voltage (Vg) curve as a voltage on the known drain current Id vs gate voltage (Vg) curve that corresponds to the current Ith, such that the extracted base threshold voltage Vt is an adjusted version of the ideal base threshold voltage Vt that is adjusted in dependence on actual varying performance among the group of memory cells.

In a further embodiment, the memory controller can be configured with logic to store one logical value of n logical values as the stored logical value represented by the stored data in each cell of the memory device, n being an integer greater than zero.

In an embodiment, n can have a value ranging from 1 to 8.

In another embodiment, the configuration circuitry can further include logic to set a ΔV voltage value according to which the base threshold voltage (Vt) is adjusted to store different logical values of the n logical values.

In a further embodiment, the configuration circuitry can include logic to minimize an error in the Euclidean distance calculated between the stored logical value and the input logical value by defining an adjustment current Iref according to which the output current is divided.

In an embodiment, the adjustment current Iref can be calculated in dependence on the set ΔV voltage value, the value of n, and the base threshold voltage (Vt).

In another embodiment, the configuration circuitry can include logic to minimize an error in the Euclidean distance calculated between the stored logical value and the input logical value by defining an adjustment current Iref according to which the output current is divided prior to determining the Euclidean distance.

In a further embodiment, the memory device can be a multi-level content addressable memory (MCAM).

In an embodiment, the memory device can be a 2D NOR flash memory, and a pair of rows in a particular column in the 2D NOR flash memory can be used to store data, and wordlines connected to the pair of rows in the particular column in the 2D NOR flash memory can be used to input data which is compared to the stored data, and one or more data words can be stored in a column of the 2D NOR flash memory.

In an embodiment, the 2D NOR flash memory can be configured at two-transistor (2T) NOR flash memory and one transistor of each 2T transistor pair can be configured to enable or disable searching on a particular row of transistors.

In a further embodiment, the 2D NOR flash memory can be configured as split-gate NOR flash memory and one gate of each transistor can be configured to enable or disable searching on a particular row of transistors.

In another embodiment, the memory device can be a 3D NOR flash memory.

In an embodiment, a memory device is provided and the memory device can include memory cells configured to store data for in-memory searching, and a memory controller configured with logic to program the memory device to store storage data according to one or more threshold voltages set in dependence on a base threshold voltage (Vt), provide one or more search voltages to the memory device in dependence on input data, the one or more search voltages being set in dependence on a base threshold voltage (Vt), and determine a level of similarity between the stored storage data and the input data according to an output current from the memory device that represents a Euclidean distance between a stored logical value represented by the stored storage data and an input logical value represented by the input data, wherein the base threshold voltage (Vt) is determined, such that the output current represents the Euclidean distance between the stored logical value represented by the stored storage data and the input logical value represented by the input data.

In a further embodiment, the base threshold voltage (Vt) can be determined in dependence on an ideal base threshold voltage Vt that is calculated by extrapolating a line with respect to known or determined characteristics of the memory device that are represented by a Id vs gate voltage (Vg) curve, where Id is a drain current provided by a memory device in response to the gate voltage (Vg).

In an embodiment, the logic to determine the base threshold voltage (Vt) can include calculating a partial derivative curve from the known or determined characteristics of the memory device that are represented by the \sqrt{Id} vs gate voltage (Vg) curve, and identifying, as the ideal base threshold voltage Vt, a value of the gate voltage (Vg) determined in dependence on a peak point of the calculated partial derivative curve and a line that is tangent to a determined point on the \sqrt{Id} vs gate voltage (Vg) curve that corresponds to the peak point, wherein the base threshold voltage (Vt) is set in dependence on the calculated ideal base threshold voltage Vt.

Further, methods can be provided to perform the operations and functionality of the memory systems described above.

For example, a method of operating memory system can be provided, where the memory system includes a memory device, a memory controller and configuration circuitry. The method can include the memory device storing data for in-memory searching, and the memory controller (i) programming the memory device, according to one or more programming voltages, to store storage data, (ii) providing one or more search voltages to the memory device in dependence on input data and (iii) determining a level of similarity between the stored storage data and the input data according to an output current from the memory device that represents a Euclidean distance between a stored logical value represented by the stored storage data and an input logical value represented by the input data. Further method can include the configuration circuitry determining a base threshold voltage (Vt) according to which the memory controller performs (i) programming the memory device using the one or more programming voltages to set one or more threshold voltages and (ii) providing the one or more search voltages, wherein the base threshold voltage (Vt) is determined, such that the output current represents the Euclidean distance between the stored logical value represented by the storage data and the input logical value represented by the input data.

Furthermore, for example a method of operating a memory device can be provided, where the memory device includes memory cells and a memory controller. The method can include storing data in the memory cells for in-memory searching. The method can further include the memory controller programming the memory device to store storage data according to one or more threshold voltages set in dependence on a base threshold voltage (Vt), providing one or more search voltages to the memory device in dependence on input data, the one or more search voltages being set in dependence on a base threshold voltage (Vt), and determining a level of similarity between the stored storage data and the input data according to an output current from the memory device that represents a Euclidean distance between a stored logical value represented by the stored storage data and an input logical value represented by the input data, wherein the base threshold voltage (Vt) is determined by the method, such that the output current represents the Euclidean distance between the stored logical value represented by the stored storage data and the input logical value represented by the input data.

Other aspects and advantages of the present invention can be seen on review of the drawings, the detailed description and the claims, which follow.

### BRIEF DESCRIPTION OF THE DRAWINGS

A detailed description of embodiments of the present invention is provided with reference to the FIGS. 1-19.

FIG. 1 illustrates an example of a two-dimensional (2D) searching memory for performing an in-memory search (IMS).

FIG. 2 illustrates an example of a three-dimensional (3D) searching memory for performing an IMS.

FIG. 3A is a graph that illustrates a drain current (Id) vs gate voltage (Vg) curve of a transistor that can be used for an IMS.

FIG. 3B is a graph that illustrates a square root of the drain current (Id) vs voltage curve of a transistor that can be used for an IMS.

FIG. 3C is a graph that illustrates a square root of the drain current (Id) divided by a calculated reference current (Iref) vs (Vg−Vt)/(Vg−Vt)ref.

FIG. 3D is a graph that illustrates Euclidean distance (L2) vs. n.

FIG. 4A is a graph that illustrates calculation of an ideal Vt using a 1 vs Vg curve.

FIG. 4B is a graph that illustrates calculation of an extracted Vt using the calculated ideal Vt and using the Id vs Vg curve.

FIG. 4C is a graph that illustrates different Iref curves with respect to Euclidean (L2) distance and n values.

FIG. 5A illustrates an example NOR flash based multi-level content addressable memory (MCAM) circuit that can be used to calculate Euclidean distance between stored data and input data.

FIG. 5B is a graph that illustrates eight threshold levels for storing data and eight voltages representing different search or input values.

FIG. 5C includes tables that describe different floating gate values representing stored data and different wordline values representing input (search) data.

FIG. 6 is a table that describes different drain current values that are provided based on a difference between a stored value and an input value.

FIG. 7 is a graph that illustrates Id vs Vg and depicts an increase in current (distance) as the difference between a stored value and an input value increases.

FIG. 8 illustrates 2D NOR based memory according to which output current increases as the difference between a stored value and an input value increases.

FIG. 9 illustrates a 2D NOR based in-memory-computing array used to compare input data to stored data and to provide a current output that represents a Euclidean distance between the input data and the stored data.

FIG. 10 illustrates a 2D NOR flash architecture according to which a search word is input on various wordlines to compare the search word to a stored data word that is stored in a column and according to which the Euclidean distance techniques can be applied to determine a distance between the search word and the stored data word.

FIG. 11 illustrates a 2T-NOR flash architecture according to which a search word is input on various MG lines to compare the search word to a stored data word that is stored in a column and according to which the Euclidean distance techniques can be applied to determine a distance between the search word and the stored data word.

FIG. 12 illustrates a split-gate NOR flash architecture according to which a search word is input on various MG lines to compare the search word to a stored data word that is stored in a column and according to which the Euclidean distance techniques can be applied to determine a distance between the search word and the stored data word.

FIG. 13 illustrates a 2D NOR flash architecture according to which two search words are input on various wordlines to compare the two search words to two stored data words stored in a column and according to which the Euclidean distance techniques can be applied to determine a distance between the search words and the stored data words.

FIG. 14 illustrates a 2T-NOR flash architecture according to which two search words are input on various wordlines to compare the two search words to two stored data words stored in a column and according to which the Euclidean distance techniques can be applied to determine a distance between the search words and the stored data words.

FIG. 15 illustrates a split-gate NOR flash architecture according to which two search words are input on various wordlines to compare the two search words to two stored data words stored in a column and according to which the Euclidean distance techniques can be applied to determine a distance between the search words and the stored data words.

FIG. 16 illustrates a split-gate NOR flash architecture according to which two search words are input on various wordlines to compare the two search words to two stored data words stored in a column, according to which various rows in the NOR flash architecture are disabled for searching purposes and according to which the Euclidean distance techniques can be applied to determine a distance between the search words and the stored data words.

FIG. 17 illustrates a 3D NOR flash architecture according to which a search word is input on various wordlines of a column of transistors of a block to compare the search word to a stored data word that is stored in a column of transistors of the block and according to which the Euclidean distance techniques can be applied to determine a distance between the search word and the stored data word.

FIG. 18 illustrates a 3D NOR flash architecture according to which a search word is input on one wordline in each of different blocks to compare the search word to a stored data word that is stored in one bitline in each of different blocks and according to which the Euclidean distance techniques can be applied to determine a distance between the search word and the stored data word.

FIG. 19 illustrates a 3D NOR flash architecture according to which a search word is input on multiple wordlines in each of different blocks to compare the search word to a stored data word that is stored in multiple bitlines in each of different blocks and according to which the Euclidean distance techniques can be applied to determine a distance between the search word and the stored data word.

FIG. 20 is a simplified block diagram of a memory system comprising memory configured for IMS using a sequence of search words and implementing the various Euclidean distance techniques described herein.

### DETAILED DESCRIPTION

The present disclosure describes techniques for determining a level or an amount of similarity between data stored in memory (e.g., a stored data word, stored logical values, etc.) and input data (e.g., an input search word, an input logical value, etc.). Specifically, these techniques can be applied to memory architectures that implement in-memory searching (IMS).

These techniques include determining a distance, such as a Euclidean distance between the stored data word (e.g., the stored logical values) and the input search word (e.g., the input logical values). If there is an exact match between the stored data word and the input search word, then the Euclidean distance will be 0. As the difference between the stored data word and the input search word increases, the Euclidean distance (as calculated) will also increase. This determined Euclidean distance can be used to made decisions based on how close or far the input search word is from the stored data word.

In mathematics a Euclidean distance (L2) is the shortest distance between two points in an N-dimensional space (e.g., Euclidean space) and can be used as a common metric to measure the similarity between two data points. Euclidean distance can be calculated as the square root of the sum of squares of differences between corresponding elements. The equation for calculating the Euclidean distance in an N-dimensional is

$$d ( p , q ) = d ( q , p ) = \sqrt{{( {q}_{1} - {p}_{1} )}^{2} + {( {q}_{2} - {p}_{2} )}^{2} + … + {( {q}_{n} - {p}_{n} )}^{2}} = \sqrt{{\sum }_{i = 1}^{n} {( {q}_{i} - {p}_{i} )}^{2}} .$$

Techniques for calculating the Euclidean distance can be implemented in a novel way to provide new techniques for determining the amount of similarity (or dissimilarity) between the input search word and the stored data word.

These techniques can include determining a base threshold voltage Vt that is used to program or write to memory cells and defining a technique for measuring current output from the memory cells when providing an input search word, so that the output current represents the Euclidean distance between the stored data word and the input search word. When there is a high similarity with respect to the stored data word and the input search word, then there is a smaller Euclidean distance and a resulting lower output current and when there is a low similarity with respect to the stored data word and the input search word, then there is a larger Euclidean distance and a resulting higher output current. These techniques can be implemented on both two-dimensional (2D) and three-dimensional (3D) NOR flashed based memory, including multi-level content addressable memory (MCAM), standard NOR architecture, as well as two-transistor (2T) NOR flash architecture, split-gate NOR architecture, as well as other types of NOR architecture.

Before the techniques for determining the similarity or dissimilarity of an input search word with respect to a stored data word are described, examples of 2D and 3D NOR memory systems that can implement these techniques will be described.

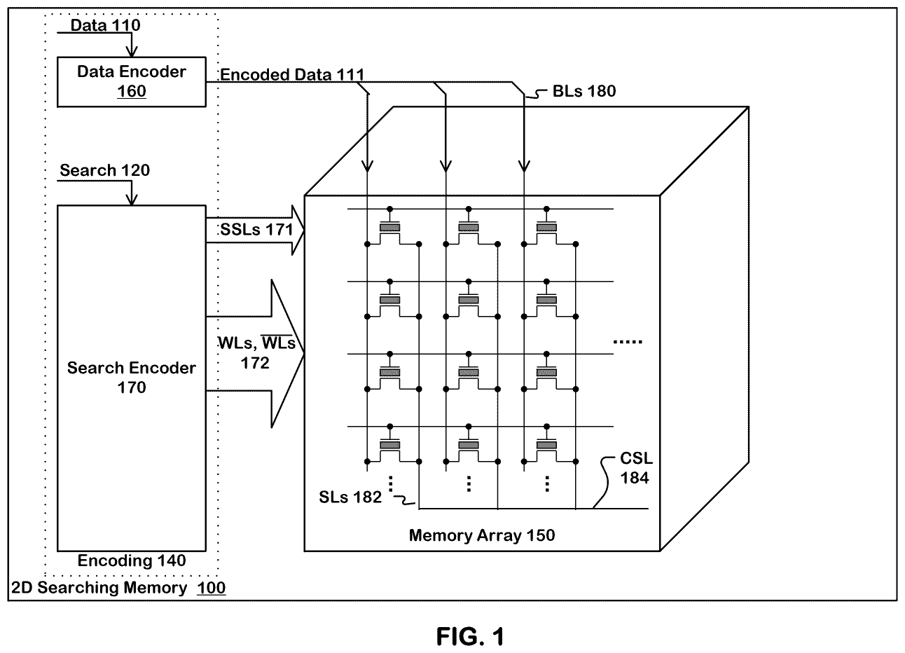

FIG. 1 illustrates an example of a two-dimensional (2D) searching memory for performing an in-memory search (IMS).

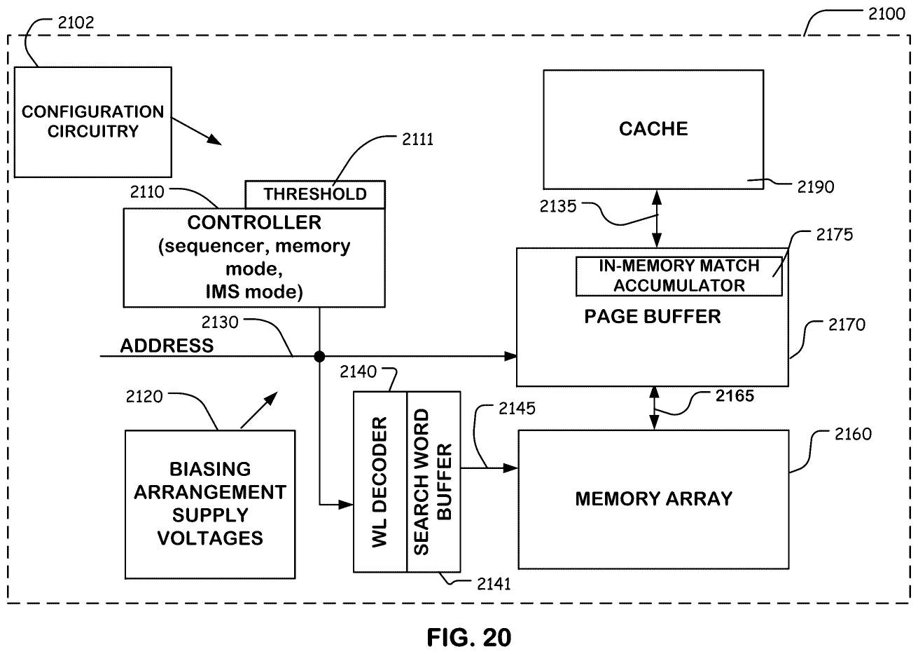

Specifically, FIG. 1 illustrates 2D searching memory 100 includes encoding resources that include data encoder 160 (e.g., data encoding circuitry), enabled to receive data 110 and in response provide encoded data 111 (e.g., programming data, data word to be stored as a stored data word, etc.) on bitlines (BLs) 180 to a memory array 150, arranged in, for example, a NOR flash memory architecture. The encoding resources further comprise search encoder 170, enabled to receive search 120 (e.g., an input data word) and in response provide string search lines, illustrated as string select lines (SSLs) 171 as well as pairs of word lines, illustrated as word wines (WLs, W̅L̅s̅) 172 to the memory array 150. The encoding performed by the encoding resources is according to a particular encoding technique, as illustrated by dotted box encoding 140. This encoding 140, as well as other memory operations, can be performed by a memory controller, as illustrated below in more detail in FIG. 20. Results of the searching (e.g., results of comparing the stored data word to the input search word) are provided on source lines (SLs) 182 to a common source line (CSL) 184. The results of the searching include currents resulting from the voltages applied to the wordlines 172 and the threshold voltages of the transistors (or switches) included in the memory array 150. Output resources of the 2D searching memory 100 can comprise sense amplifiers, etc. connected to the SLs 182 and/or the CSL 184.

For clarity, the figure omits selected details such as relating to programming and erasing programmable memory devices of the 2D memory arrays.

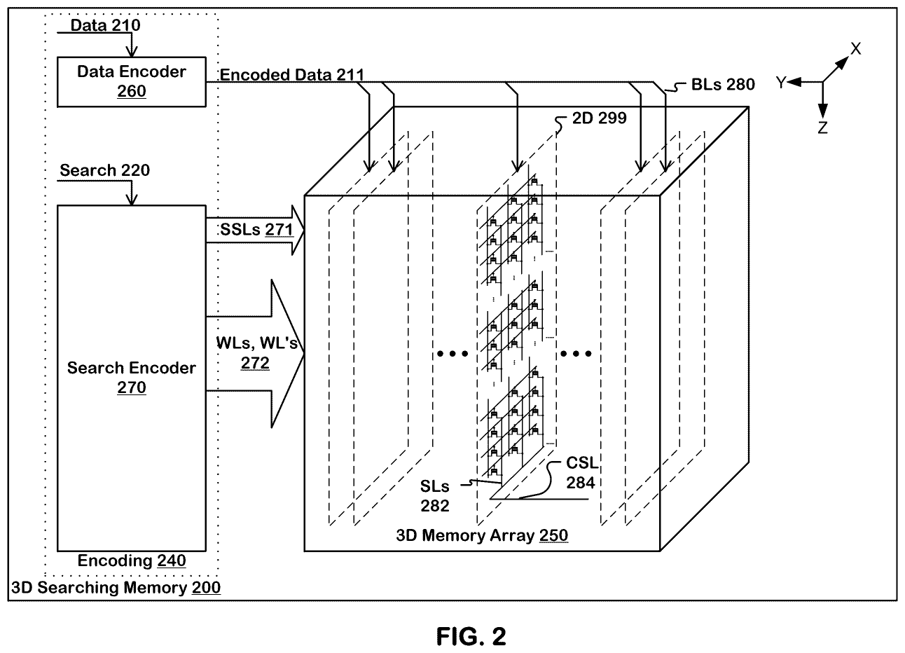

FIG. 2 illustrates an example of a three-dimensional (3D searching memory for performing an IMS.

FIG. 2 illustrates an example of a 3D searching memory 200 implemented in three dimensions (X, Y, and Z) that includes encoding resources that include data encoder 260 (e.g., data encoding circuitry), enabled to receive data 210 and in response provide encoded data 211 (e.g., programming data, data word to be stored as a stored data word, etc.) on bitlines (BLs) 280 to a 3D memory array 250, arranged in, for example, a NOR flash architecture. The encoding resources further comprise search encoder 270, enabled to receive search 220 (e.g., an input data word) and in response provide string search lines, illustrated as string select lines (SSLs) 271 as well as pairs of word lines, illustrated as word lines (WLs, WLs) 272 to the 3D memory array 250. The encoding performed by the encoding resources is according to a particular encoding technique, as illustrated by dotted box encoding 240. This encoding 240, as well as other memory operations, can be performed by a memory controller, as illustrated below in more detail in FIG. 20. Results of the searching (e.g., results of comparing the stored data word to the input search word) are provided on source lines (SLs) 282 to a common source line (CSL) 184. The results of the searching include currents resulting from the voltages applied to the wordlines 172 and the threshold voltages of the transistors (or switches) included in the 3D memory array 250. The 3D memory array 250 can include a plurality of instances of 2D memory arrays, one of which is specifically identified as 2D Memory Array (2D) 299. Output resources of the 3D searching memory 200 can comprise sense amplifiers, etc. connected to the SLs 282 and/or the CSL 284.

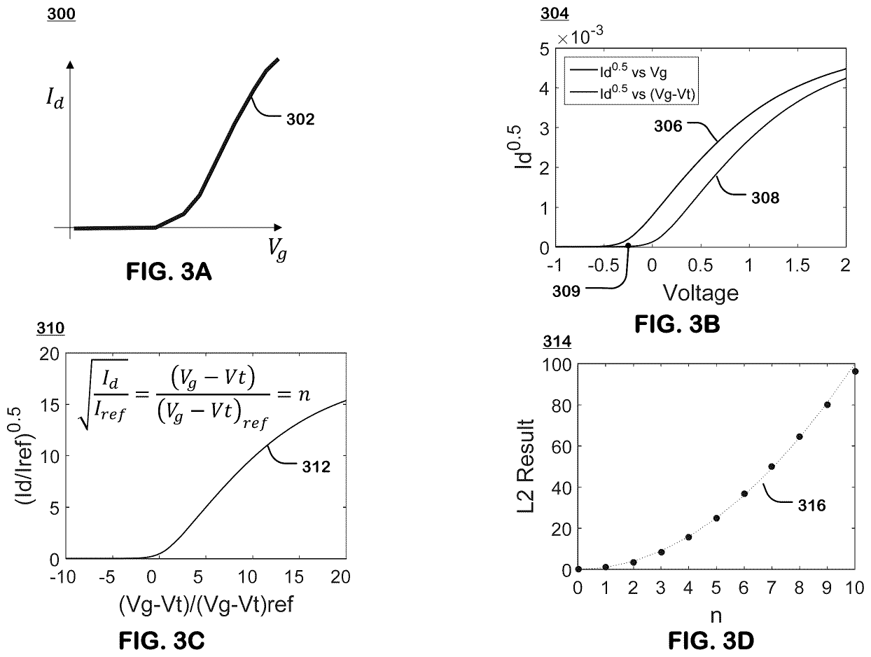

FIG. 3A is a graph 300 that illustrates a drain current (Id) vs gate voltage (Vg) curve of a transistor that can be used for an IMS.

Specifically, FIG. 3A illustrates an example drain current (Id) vs gate voltage (Vg) curve 302 that is known for any type of cell (e.g., a switch or transistor) that can be used in a memory device. Throughout this document, the term transistor can be interpreted as any type of cell of a memory device, including a basic switch. Further, the term transistor can mean any type of transistor such as a metal-oxide semiconductor field-effect transistor (MOSFET), including NMOS and PMOS types. This drain current (Id) vs gate voltage (Vg) curve 302 can be a result of measuring characteristics of a particular transistor based on various voltages and/or currents being applied to the gate, source and/or drain. The drain current (Id) vs gate voltage (Vg) curve 302 can be provided by the manufacturer of the transistor and/or it can be based on actual measurements taken at any given point in time throughout the life of the transistor.

As illustrated, the drain current (Id) is represented by the Y-axis and the gate voltage (Vg) is represented by the X-axis. Most transistors behave in such a way that the curve 302 flattens as the gate voltage (Vg) increases sufficiently to put the transistor in a saturation region of operation (e.g., the drain current (Id) remains the same, even as the gate voltage (Vg) increases). This saturation region of operation is not provided in the curve 302.

FIG. 3B is a graph 304 that illustrates a square root of the drain current (Id) vs voltage curve of a transistor that can be used for an IMS.

Specifically, FIG. 3B illustrates an example a \sqrt{Id} vs gate voltage (Vg) curve 306 and an example \sqrt{Id} vs gate voltage (Vg) minus threshold voltage (Vt) curve 308. The example \sqrt{Id} vs gate voltage (Vg) curve 306 can be derived from the curve 302 illustrated in FIG. 3A. Curve 308 is essentially the same as curve 306, just shifted to the right by the amount of the threshold voltage (Vt) for the particular transistor.

One of the techniques of determining the similarity between the stored data word and the input search word is to determine a base threshold voltage (Vt) to implement when storing and inputting logical values for the IMS. The base threshold voltage (Vt) can be the lowest threshold voltage usable to store a certain value in a transistor or a pair of transistors. For example, if a floating gate transistor is used to store one of 8 values (e.g., one of 8 possible logical values), the threshold voltage of the floating gate transistor can be programmed to any of 8 different voltages. These 8 different voltages can be described as Vt0, Vt1, Vt2, Vt3, Vt4, Vt5, Vt6 and Vt7 or also described as Vt0-Vt7. The base threshold voltage (Vt) can be set to equal Vt0 and then each additional voltage Vt1-Vt7 can be set to be incrementally higher than Vt0. In some embodiments the “increment” can be the same for each additional voltage and in some embodiments the “increment” can be different for each additional voltage in the range.

In an embodiment, the base threshold voltage (Vt) (or referred to as the ideal base threshold voltage Vt or the extracted base threshold voltage Vt) can be set to a voltage at which \sqrt{Id} becomes proportional to (Vg−Vt). As illustrated the base threshold voltage (Vt) 309 is a point on the graph where \sqrt{Id} starts to become proportional to (Vg−Vt). In other words, base threshold voltage (Vt) can be defined where drain current (Id) can be found with a square ratio. Additional techniques for determining the base threshold voltage (Vt) are discussed below.

FIG. 3C is a graph 310 that illustrates a square root of the drain current (Id) divided by a calculated reference (adjustment) current (Iref) vs (Vg−Vt)/(Vg−Vt)ref.

Specifically, FIG. 3C illustrates a graph where the Y-axis represents a square root of the drain current (Id) divided by a calculated adjustment current (Iref). Calculation of the adjustment current (Iref) is described below in more detail. The purpose of the adjustment current (Iref) is to adjust the drain current (Id) so that it provides a more accurate representation of the Euclidean distance between the stored data and the input data.

The X-axis represents (Vg−Vt)/(Vg−Vt)ref, where (Vg−Vt)ref can be equal to ΔV, which represents the incremental change in voltage between, for example, Vt0 and Vt1, and between Vt1 and Vt2, etc. The amount of ΔV can be selected from a range of available voltages. For example, ΔV can be between 0.05V and 0.3V. If ΔV is at the lower end of the 0.05V to 0.3V range, then the L2 result can be more correct at higher values of n. If the ΔV is at the higher end of the range or above the range, then the transistor will reach the saturation region when the n is higher. “n” is the ratio of (Vg−Vt)/ΔV. That is, if you want to support L2 calculation up to n=X, the applied Vg is Vt+X*ΔV, and this applied Vg cannot make the transistor in the saturation region.

As illustrated in FIG. 3C, n (which is the number of possible logical values to be stored in the transistor) can equal the ratio of (Vg−Vt)/(Vg−Vt)ref, which can also equal, for a given drain current (Id), \sqrt{Id/Iref}, as illustrated by curve 312. When a ΔV value is selected and Iref is determined, and the Vt of the device is determined or known, then Vg can be applied on the device and define n equal to (Vg−Vt)/ΔV. Then the transistor Id drain current can be determined at the applied Vg and the Euclidean distance L2 result can be obtained by Id/Iref.

FIG. 3D is a graph 314 that illustrates Euclidean distance (L2) vs. n.

Specifically, FIG. 3D illustrates a curve 316 of the Euclidean distance L2 results being the square of n. Specifically, this illustrates that the further away an input value is from a stored value, the larger the Euclidean distance. For example, if a stored (logical) value is 0 and an input (logical) value is 5, then the Euclidean distance between the logical values is 25, because n=5 in this example. In the graph 314, the dashed or dotted line is an ideal L2 distance of n squared and the dots are actual experimental results.

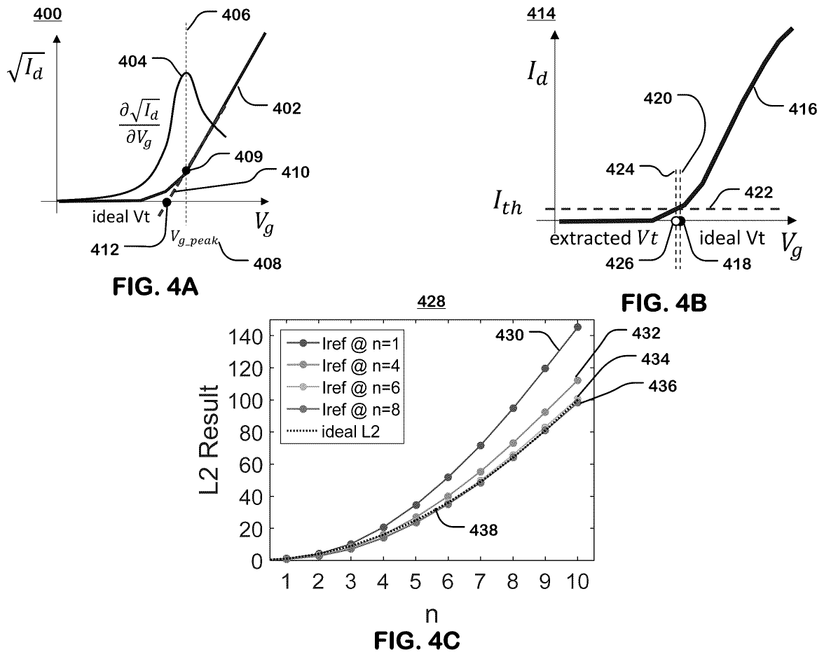

FIG. 4A is a graph 400 that illustrates calculation of an ideal Vt using a \sqrt{Id} vs Vg curve.

Specifically, FIG. 4A is a graph 400 that helps to illustrate how the ideal base threshold voltage Vt (ideal Vt) is calculated. Initially, a \sqrt{Id} vs Vg curve 402 is obtained or determined, for a transistor. An example of the \sqrt{Id} vs Vg curve 402 is the curve 306 of FIG. 3B. Curve 402 can be obtained several ways, as discussed above. Further, a partial derivative of the curve 402 is calculated (see curve 404). As illustrated, curve 404 is obtained by calculating ∂\sqrt{Id}/∂V g. A peak of the curve 404 is identified and then a voltage value of Vg is taken from the curve 404. Specifically, the vertical dashed line 406 is placed at the peak of the curve 404, and voltage Vg_peak 408 is identified at a location where the line 406 crosses the X-axis of the plot. The value of Vg_peak 408 is based on the peak \sqrt{Id} value taken from the partial derivative curve 404. In other words, the Vg_peak 408 is a voltage that aligns with the peak point of the calculated partial derivative curve 404.

The Vg_peak 408 is used to identify a point 409 on the \sqrt{Id} vs Vg curve 402. In other words, the point 409 on the \sqrt{Id} vs Vg curve 402 that corresponds to the Vg_peak 408 is identified. Then from point 409 a line 410 that is tangent to the point 409 is calculated (and extrapolated) in dependence on the slope of the partial derivative curve 404. In other words, the slope of the peak of the partial derivative curve 404 can be used to calculate the slope of the line 410 that is tangent to point 409. The slope of line 410 can be determined using other values or calculations derived from curve 404.

A point 412 at which the line 410 intersects the X-axis is determined to be the ideal base threshold voltage Vt (ideal Vt). In other words, ideal Vt can be represented as the voltage value on line 410 where \sqrt{Id}=0. This ideal Vt can represent a lowest threshold voltage that is usable to store values and input data for determining the Euclidean distance between the stored values (e.g., storage data, stored data word, etc.) and input data (e.g., input search word). As explained in more detail below, the value of the calculated ideal Vt can be used as both the lowest programmed threshold voltage for the transistor and the lowest voltage to represent an input search word. Ideal Vt can be represented as voltage Vtn, where n=0. For example, if it is determined that the transistor is to be capable of storing 8 values, then the voltages used to store the 8 values are represented as voltages Vt0 through Vt7, with the difference between each voltage (e.g., voltage Vt0 and voltage Vt1) being an increment represented at ΔV. This range of voltages Vtn is the range of threshold voltages usable to program the transistor. More examples are provided below. Even though voltage Vt0 is near ideal Vt, voltage Vt0 does not necessarily need to equal ideal Vt. Vt0 can be extracted Vt or ideal Vt.

FIG. 4B is a graph 414 that illustrates calculation of an extracted Vt using the calculated ideal Vt and using the Id vs Vg curve.

The techniques described herein can be used to calculate an extracted Vt (also referred to as extracted base threshold voltage Vt) based on the ideal Vt discussed above with respect to FIG. 4A. The process for calculating the extracted Vt can be performed as follows: (i) obtaining the Id vs Vg curve 416 that is known for the transistor, such as the curve 302 discussed above with respect to FIG. 3A, (ii) identifying a current value Id on the curve 416 that corresponds to the ideal Vt (see point 418 on the X-axis which represents the ideal Vt and the vertical dashed line 420 that intersects the curve 416, where the point of intersection represents the identified current value Id, (iii) using a group of transistors that are selected based on the transistor for which the curve 416 is obtained, determining a median current value Id that corresponds to the ideal Vt (in other words using a group of actual transistors or simulated transistors, the calculated ideal Vt is used to determine the median current value Id), (iv) define the determined median current value Id as current value Ith, as represented by line 422, and (v) calculate a based extracted threshold voltage Vt (extracted Vt) based on a point at which current value Ith (line 422) intersects curve 416 (see vertical line 424 that intersects the point on curve 416 represented current value Ith, where extracted Vt 426 is determined to be the voltage value at where line 424 intersects the X-axis).

As a result, extracted Vt 426 is based on a result of measurements obtained from a group of transistors, such that ideal Vt is adjusted based on the actual performance of many transistors to obtain extracted Vt. The techniques describe with respect to FIG. 4A to determined ideal Vt can be obtained “offline” without actually live testing of transistors, whereas the techniques described with respect to FIG. 4B can be obtained “online” using actual live testing (or simulation) of transistors.

FIG. 4C is a graph 428 that illustrates different Iref curves with respect to Euclidean (L2) distance and n values.

Before the graph 428 is explained, the purpose and method of calculating an adjustment current Iref will be explained. The adjustment current Iref can be determined to minimize error in the calculated Euclidean distance. Adjustment current Iref can be defined as a base current for calculating the Euclidean distance, such that the Euclidean distance=Id/Iref. In other words, the measured drain current Id is divided by the adjustment current Iref to obtain a more accurate value of the Euclidean distance between stored data and input data.

For flash memory, the current Id characteristics do not follow drain current Id being proportional to (Vg−Vt)² for all voltage values of Vg, which can result in errors in the calculation of the Euclidean distance. In order to minimize this error, the adjustment current Iref can be calculated to minimize the error, where the value of the adjustment current Iref can be based on the determined value of n, where the maximum value of n equals the number of logical values that can be stored (or input) and the value of n is changed to represent which of the logical values is being stored (or input).

Adjustment current

$$Iref = \frac{Idn}{{n}^{2}} ,$$

where Idn=Id|(Vg−Vt)=ΔV×n. In other words, adjustment current Iref is calculated for a value of n using the drain current Idn calculated for that value of n, where ΔV is a predetermined value that represents the incremental voltage change that is set to determine the different drain current Id values. Note that

$$n = \frac{( Vg - Vt )}{Δ V} ,$$

where Vt in this equation can be the calculated ideal Vt or the extracted Vt. Using the adjustment current

$$Iref = \frac{Idn}{{n}^{2}}$$

formula, here are some examples: (i) if Iref is defined at n=1, then

$$Ir ef = \frac{Id 1}{1} ,$$

(ii) if Iref is defined at n=2, then

$$Ir ef = \frac{Id 2}{4} ,$$

(iii) if Iref is defined at n=3, then

$$Ir ef = \frac{Id 3}{9} ,$$

(iv), if Iref is defined at n=4, then

$$Iref = \frac{Id 4}{16} ,$$

(v) if Iref is defined at n=5, then

$$Iref = \frac{Id 5}{25} ,$$

(vi), if Iref is defined at n=6, then

$$Iref = \frac{Id 6}{36} ,$$

(vii) if Iref is defined at n=7, then

$$Iref = \frac{Id 7}{49} ,$$

and (viii) if Iref is defined at n=8, then

$$Iref = \frac{Id 8}{64} .$$

As illustrated in the graph 428, different Iref curves are plotted for different n values. For example, curve 430 represents an Iref plot for n=1, curve 432 represents an Iref plot for n=4, curve 434 represents an Iref plot for n=6, curve 436 represents an Iref plot for n=8 and curve 438 represents an ideal plot. As illustrated curve 434 and curve 436 are closest to the ideal curve 438. As illustrated, according to curve 436 which represents using Iref calculated using n=8, if the n value on the X-axis is 8 (meaning that there is a different of 8 between the stored value and the input value), then the Euclidean distance result will be approximately 60, whereas according to curve 430 which represents using Iref calculated using n=1, if the n value on the X-axis is also 8, then the Euclidean distance result will be just below 100. As illustrated, using different Iref values can change the Euclidean distance calculation significantly. Iref @n=6 is close to the ideal calculation and Iref @n=8 is the closest to the ideal calculation.

As discussed, ΔV can have a range between 0.05V and 0.3V. Characteristics of a transistor can follow

$$\sqrt{\frac{Id}{Iref}} = \frac{( Vg - Vt )}{( Vg - Vt ) ref} , where$$

$$n = \frac{( Vg - Vt )}{( Vg - Vt ) ref} = \frac{( Vg - Vt )}{Δ V} ,$$

because ΔV=(Vg−Vt)ref, and

$$Euclidean distance = \frac{Id \vert Vg = ( Vt + Δ V \times n )}{Iref} .$$

Using these formulas, example calculations are provided below.

For ΔV=0.05V and extracted

$$Vt ( or ideal Vt ) = 0.5 V : n = \frac{( Vg - Vt )}{( Vg - Vt ) ref} = \frac{( Vg - Vt )}{Δ V} = \frac{( Vg - 0. 5 )}{0.05} , and$$

$$Euclidean distance = \frac{Id ( measured at Vg = ( 0.05 n + 0.5 ) )}{Iref} .$$

For ΔV=0.1V and extracted

$$Vt ( or ideal Vt ) = 0.5 V : n = \frac{( Vg - Vt )}{( Vg - Vt ) ref} = \frac{( Vg - Vt )}{Δ V} = \frac{( Vg - 0. 5 )}{0.1} , and$$

$$Euclidean distance = \frac{Id ( measured at Vg = ( 0.1 n + 0.5 ) )}{Iref} .$$

For ΔV=0.3V and extracted

$$Vt ( or ideal Vt ) = 0.3 V : n = \frac{( Vg - Vt )}{( Vg - Vt ) ref} = \frac{( Vg - Vt )}{Δ V} = \frac{( Vg - 0. 3 )}{0.3} ,$$

$$Euclidean distance = \frac{Id ( measured at Vg = ( 0.3 n + 0.3 ) )}{Iref} .$$

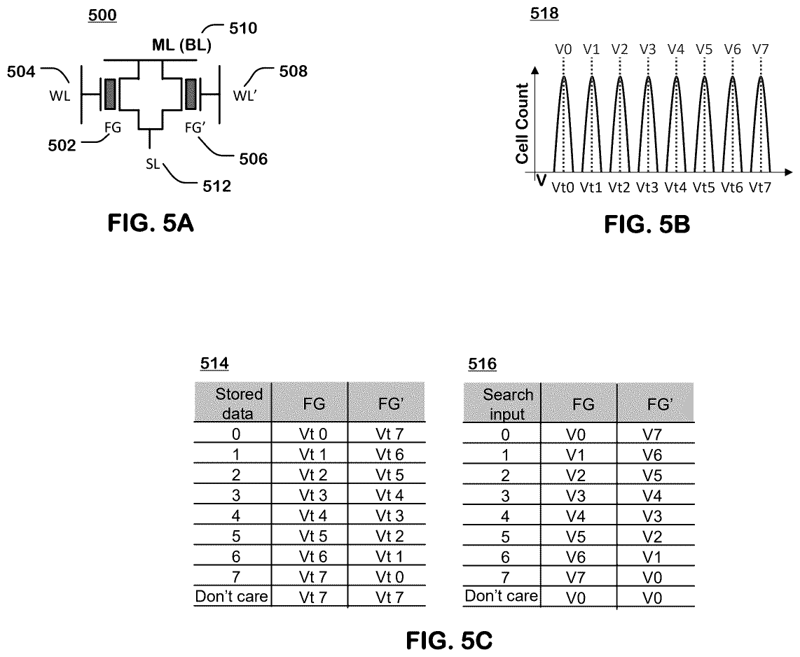

FIG. 5A illustrates an example NOR flash based multi-level content addressable memory (MCAM) circuit that can be used to calculate Euclidean distance between stored data and input data.

Specifically, FIG. 5A illustrates an MCAM circuit 500 that can be implemented to perform IMS using the techniques described herein. The MCAM circuit 500 includes floating gate (FG) transistor 502 and floating gate (FG′) transistor 506. Transistor 502 includes a gate connected to a wordline (WL) 504, a terminal, such as a source terminal, connected to a match line (ML), e.g., bitline (BL) 510 and a drain terminal connected to a source line 512. Transistor 506 includes a gate connected to a wordline (WL′) 508, a terminal, such as a source terminal, connected to the match line (ML), e.g., bitline (BL) 510, and a terminal, such as a drain terminal, connected to the source line (SL) 512. A search input representing a logical input value can be encoded using (predetermined) voltages on wordline (WL) 504 of transistor 502 and wordline (WL′) 508 of transistor 506. The search input on the pair of wordlines 504, 508 can represent one bit of a logical value. The search input can be compared to a stored value (e.g., a bit of data represented by values stored by transistors 502, 506). For example, a stored data bit can be stored as two threshold voltages on transistors 502, 506. As discussed in more detail below with reference to FIG. 5C, a stored data value (e.g., a stored data bit) is represented by threshold voltages of two transistors 502, 506, where the threshold voltages are programmed based on the desired value of the data bit, and the search input value (e.g., a data bit to be compared to the stored data bit) is represented by voltages applied to the two wordlines 504, 508. The outputs of the transistors 502, 506 will be dependent upon how close the search input value (e.g., search voltages) is to the stored data value (e.g., threshold voltages). Example behavior of the transistors 502, 506 is described below.

In an embodiment, when a search voltage applied to wordline (WL) 504 falls within a match range of the value (e.g., the threshold voltage representing the stored data bit) of transistor 502 then a voltage on the bitline (BL) 510 will not be discharged by transistor 502, such that there is no current output on the drain of the transistor 502 to the source line 512. Similarly, when a search voltage applied to wordline (WL′) 508 falls within a match range of the value (e.g., the threshold voltage representing the stored data bit) of transistor 506 then a voltage on the bitline (BL) 510 will not be discharged by transistor 506, such that there is no current output on the drain of the transistor 506 to the source line 512. The zero current (or very low current) on the source line 512 will then indicate that there is a match between the search voltage and the stored logical value represented by the threshold voltages of the transistors 502 and 506.

Additionally, when a search voltage applied to wordline (WL) 504 does not fall within a match range of the value (e.g., the threshold voltage representing the stored data bit) of transistor 502 then a voltage on the bitline (BL) 510 will be discharged by transistor 502 in dependence on a difference between the search voltage and the (programmed) threshold voltage of transistor 502 (e.g., in proportion to the square of the difference between the search voltage and the (programmed) threshold voltage of transistor 502), such that there is current output on the drain of the transistor 502 to the source line 512 in dependence on (e.g., in proportion to) the search voltage. Similarly, when a search voltage applied to wordline (WL) 508 does not fall within a match range of the value (e.g., the threshold voltage representing the stored data bit) of transistor 506 then a voltage on the bitline (BL) 510 will be discharged by transistor 506 in dependence on a difference between the search voltage and the (programmed) threshold voltage of transistor 506 (e.g., in proportion to the square of the difference between the search voltage and the (programmed) threshold voltage of transistor 506), such that there is current output on the drain of the transistor 506 to the source line 512 in dependence on (e.g., in proportion to) the search voltage.

FIG. 5B is a graph 518 that illustrates eight threshold levels for storing data and eight voltages representing different search or input values and distributions of memory cells.

Specifically, FIG. 5B illustrates distributions of memory cells, like those illustrated in FIG. 5A or any other memory cells disclosed herein. In FIG. 5B the X-axis corresponds to voltage and the Y-axis corresponds to quantities of memory cells.

As shown in FIG. 5B, memory cells can have distributions corresponding to threshold voltages Vt, as Vt0, Vt1, Vt2, Vt3, Vt4, Vt5, Vt6 and Vt7 (Vt0-Vt7). In response to being programmed to store data, each memory cell can have threshold voltage levels (Vt0-Vt7) that corresponds to the value being stored. Further, as shown in FIG. 5B, voltage levels V0, V1, V2, V3, V4, V5, V6 and V7 (V0-V7) are arranged in order along the X-axis and are located at the peaks of the distributions of the threshold voltage levels Vt0-Vt7. The voltage levels V0-V7 can be referred to as search or input voltage levels.

FIG. 5C includes tables 514 and 516 that describe different floating gate values representing stored data and different wordline values representing input (search) data.

Specifically, table 514 illustrates different threshold voltage Vt values used to store different logical values, e.g., table 514 illustrates a particular encoding of logical values to (programmed) threshold voltages. For example, in order to store a logical value of 0, transistor 502 would be programmed with a threshold voltage that corresponds to Vt0 and transistor 506 would be programmed with a threshold voltage that corresponds to Vt7, in order to store a logical value of 1, transistor 502 would be programmed with a threshold voltage that corresponds to Vt1 and transistor 506 would be programmed with a threshold voltage that corresponds to Vt6, in order to store a logical value of 2, transistor 502 would be programmed with a threshold voltage that corresponds to Vt2 and transistor 506 would be programmed with a threshold voltage that corresponds to Vt5, in order to store a logical value of 3, transistor 502 would be programmed with a threshold voltage that corresponds to Vt3 and transistor 506 would be programmed with a threshold voltage that corresponds to Vt4, in order to store a logical value of 4, transistor 502 would be programmed with a threshold voltage that corresponds to Vt4 and transistor 506 would be programmed with a threshold voltage that corresponds to Vt3, in order to store a logical value of 5, transistor 502 would be programmed with a threshold voltage that corresponds to Vt5 and transistor 506 would be programmed with a threshold voltage that corresponds to Vt2, in order to store a logical value of 6, transistor 502 would be programmed with a threshold voltage that corresponds to Vt6 and transistor 506 would be programmed with a threshold voltage that corresponds to Vt1, and in order to store a logical value of 7, transistor 502 would be programmed with a threshold voltage that corresponds to Vt7 and transistor 506 would be programmed with a threshold voltage that corresponds to Vt0. Since this can be implemented using MCAM technology, the transistors 502 and 506 can be programmed to have “don't care” values as well (e.g., Vt7). The values for Vt0-Vt7 can be determined using the techniques described herein, such that Vt0-Vt7 are based on the ideal Vt or the extracted Vt and the voltage difference between each Vt level is dictated by ΔV.

Table 516 illustrates different search voltages that represent input search values that are compared to the stored data, e.g., table 516 illustrates a particular encoding of input search values to wordline and wordline′ (WL′) voltages (e.g., search voltages). The encoding illustrated by table 514 for stored values is compatible with searching using the encoding illustrated by table 516 for wordline (WL) and wordline′ (WL) voltages (e.g., search voltages). For example, a search input value of 0 is represented by providing a voltage that corresponds to V0 to the wordline (WL) 504 of transistor 502 and by providing a voltage that corresponds to V7 to the wordline (WL′) 508 of transistor 506, a search input value of 1 is represented by providing a voltage that corresponds to V1 to the wordline (WL) 504 of transistor 502 and by providing a voltage that corresponds to V6 to the wordline (WL′) 508 of transistor 506, a search input value of 2 is represented by providing a voltage that corresponds to V2 to the wordline (WL) 504 of transistor 502 and by providing a voltage that corresponds to V5 to the wordline (WL′) 508 of transistor 506, a search input value of 3 is represented by providing a voltage that corresponds to V3 to the wordline (WL) 504 of transistor 502 and by providing a voltage that corresponds to V4 to the wordline (WL′) 508 of transistor 506, a search input value of 4 is represented by providing a voltage that corresponds to V4 to the wordline (WL) 504 of transistor 502 and by providing a voltage that corresponds to V3 to the wordline (WL′) 508 of transistor 506, a search input value of 5 is represented by providing a voltage that corresponds to V5 to the wordline (WL) 504 of transistor 502 and by providing a voltage that corresponds to V2 to the wordline (WL′) 508 of transistor 506, a search input value of 6 is represented by providing a voltage that corresponds to V6 to the wordline (WL) 504 of transistor 502 and by providing a voltage that corresponds to V1 to the wordline (WL′) 508 of transistor 506, and a search input value of 7 is represented by providing a voltage that corresponds to V7 to the wordline (WL) 504 of transistor 502 and by providing a voltage that corresponds to V0 to the wordline (WL′) 508 of transistor 506. Since this can be implemented using MCAM technology, the transistors 502 and 506 can be provided with a search input that represents “don't care” values as well, where both transistors 502 and 506 receive voltages V0. The values for V0-V7 can be determining using the techniques described herein, such that V0-V7 can be based on the ideal Vt or the extracted Vt and the voltage difference between each Vt level is dictated by ΔV.

This is just an example of using MCAM to store 8 logical values. The transistors can be configured to store more (logical) values or fewer (logical) values.

With respect to FIGS. 5A, 5B and 5C, Vtᵢ₊₁−Vtᵢ=Vᵢ₊₁−Vᵢ=ΔV, where Vᵢ is at the peak of a Vtᵢ distribution, and where i=0 through 6 for this example. Vtₙ=Vt₀+n×ΔV, where n=0 through 7 for this example. Vt₀ to Vtₙ can be equal to or closely based on the ideal Vt or the extracted Vt.

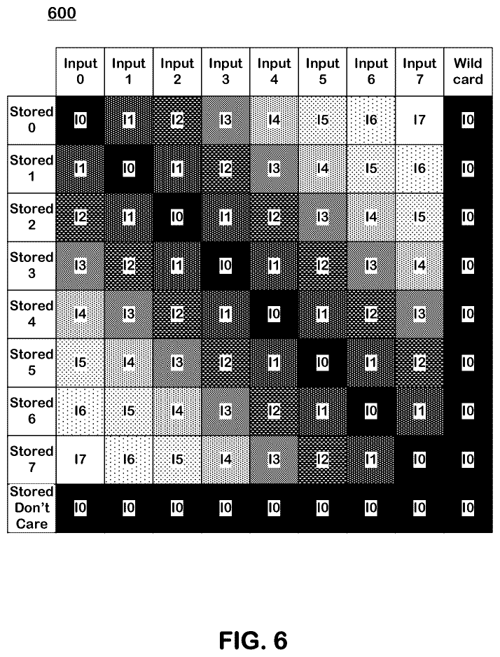

FIG. 6 is a table 600 that describes different drain current values that are provided based on a difference between a stored value and an input value.

Specifically, the table 600 illustrates that for a stored value of 0 and an input (search) value of 0, the drain current can be represented as I0, which indicates that there is essentially a match between the stored value and the input value. In other words, the Euclidean distance between the stored value and the input value is 0. Drain current I0 can correspond to drain current Id0 or Id(n=0). Further, as illustrated, as the input value increases from 0 to 7 and the stored value remains at 0, the drain current respectively increases as current I1, current I2, current I3, current I4, current I5, current I6 and current I7. These currents I1 through I7 can be represented by drain currents Id1 through Id7. The table 600 further illustrates that for a stored value of 1 and an input (search) value of 0, the drain current can be represented by I1. As the input (search) value increases to 1 and the stored value remains at 1, the drain current decreases to current I0, indicating a match between the stored value and the input value. As the input (search) value increases from 2 to 7 and the stored value remains at 1, the drain current respectively increases as currents I1, I2, I3, I4, I5, and I6. The table 600 further illustrates corresponding behavior for stored values of 2 through 7. In relation to FIG. 5A, the currents I1 through I7 in the left-hand diagonal portion of the table 600 are through floating gate (FG) transistor 502, floating gate (FG′) transistor 506 being off. Similarly, in relation to FIG. 5A, the currents I1 through I7 in the right-hand diagonal portion of the table 600 are through floating gate (FG′) transistor 506, floating gate (FG) transistor 502 being off.

In this example the Euclidean distance

$${n}^{2} = \frac{{I}_{n}}{{I}_{1}} ,$$

where n can equal 1 through 7 and I₀ (or I0)<I₁ (or I1).

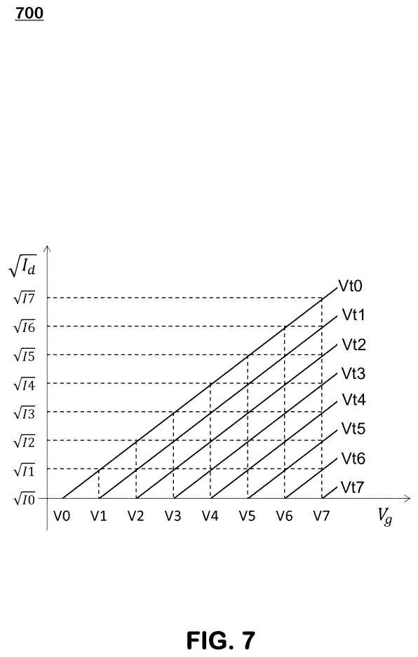

FIG. 7 is a graph 700 that illustrates \sqrt{Id} vs Vg and depicts an increase in current (distance) as the difference between a stored value and an input value increases.

Specifically, the line labelled Vt0 illustrates that the \sqrt{Id} current value increases as the gate voltage Vg becomes greater than V0, such that when the gate voltage Vg has a value of V0 that equals the Vt0 value, then the \sqrt{Id} current value is 0 (e.g., \sqrt{I0}) and such that when the gate voltage Vg has a value of V7, which is different from the Vt0 value, then the \sqrt{Id} current value becomes the \sqrt{I7}, which indicates a larger Euclidean distance. The same principle holds for lines Vt1 through Vt7.

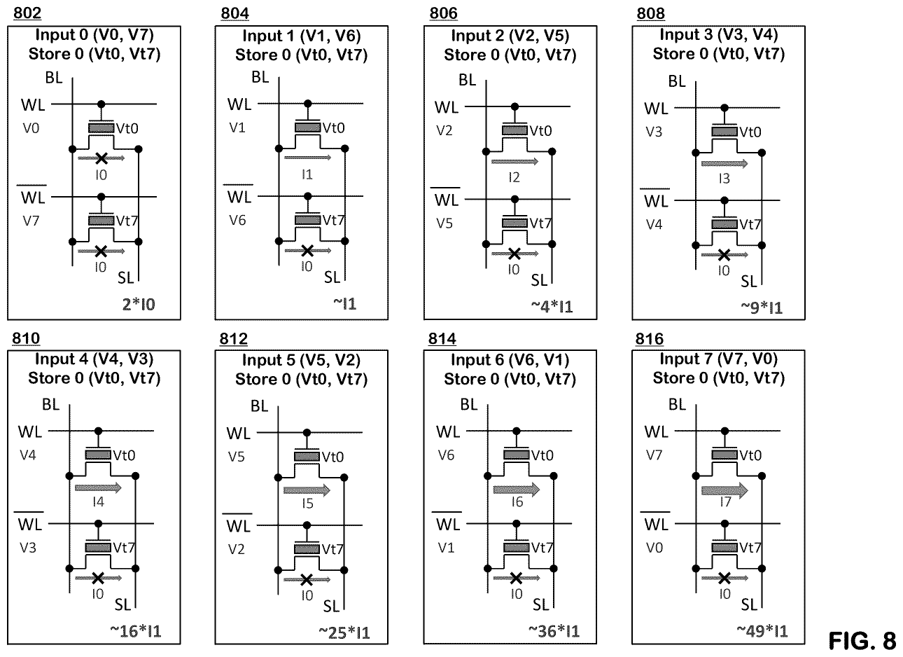

FIG. 8 illustrates 2D NOR based memory according to which output current increases as the difference between a stored value and an input value increases.

In FIG. 8, the current output on source line (SL) represents the Euclidean distance between an input query and stored content. Lower output current represents a smaller Euclidean distance (e.g., high similarity) between the input query and the stored content and a higher output current represents a larger Euclidean distance (e.g., low similarity) between the input query and the stored content.

Here, example 802 represents a logical input value of 0 and a logical stored value of 0. As discussed previously, the logical value of 0 is stored by setting the threshold voltage Vt of the upper transistor to Vt0 (e.g., based on a base threshold voltage Vt, an ideal base threshold voltage or an extracted base threshold voltage Vt), and the threshold voltage Vt of the lower transistor to Vt7. This is just an example of storing a logical value of 0 and other techniques can be implemented. The logical value of 0 is input as the input query by providing voltage V0 on the wordline (WL) of the upper transistor and by providing voltage V7 on the wordline bar (W̅L̅). As illustrated, because V0 is essentially the same as (or less than) Vt0, no current will flow through the upper transistor and because V7 is essentially the same as (or less than) Vt7, no current will flow through the upper transistor. In other words, because V0 is not more than Vt0, and because V7 is not more than Vt7, both transistors are turned off, thus, indicating that there is a match. This lack of current flow is represented as I0, such that the current on source line (SL) is 2 times I0 (or 0).

Example 804 represents a logical input value of 1 and a logical stored value of 0. As discussed previously, the logical value of 0 is stored by setting the threshold voltage Vt of the upper transistor to Vt0 and the threshold voltage Vt of the lower transistor to Vt7. This is just an example of storing a logical value of 0 and other techniques can be implemented. The logical value of 1 is input as the input query by providing voltage V1 on the wordline (WL) of the upper transistor and by providing voltage V6 on the wordline bar (WL). As illustrated, because V1 is greater than Vt0, a current of I1 will flow through the upper transistor and because V6 is less than Vt7 no current will flow through the lower transistor. In other words, because V1 is more than Vt0 and because V6 is not more than Vt7, the upper transistor is turned on and the lower transistor is turned off. Thus, indicating that there is a mismatch between the input value and the stored value. The current flow is represented as I1, such that the current on source line (SL) is approximately I1.

Example 806 represents a logical input value of 2 and a logical stored value of 0. As discussed previously, the logical value of 0 is stored by setting the threshold voltage Vt of the upper transistor to Vt0 and the threshold voltage Vt of the lower transistor to Vt7. The logical value of 2 is input as the input query by providing voltage V2 on the wordline (WL) of the upper transistor and by providing voltage V5 on the wordline bar (WL). As illustrated, because V2 is more than Vt0, a current of I2 will flow through the upper transistor and because V5 is less than Vt7 no current will flow through the lower transistor. In other words, because V2 is more than Vt0 and because V5 is not more than Vt7, the upper transistor is turned on and the lower transistor is turned off. The current I2 is greater than the current I1 from example 804 because the voltage V2 is greater than voltage V1. This indicates that there is greater mismatch between the input value and the stored value in example 806 when compared to the mismatch in example 804. The current flow is represented as I2, such that the current on source line (SL) is approximately I2, which is approximately 4 times current I1.

Example 808 represents a logical input value of 3 and a logical stored value of 0. As discussed previously, the logical value of 0 is stored by setting the threshold voltage Vt of the upper transistor to Vt0 and the threshold voltage Vt of the lower transistor to Vt7. The logical value of 3 is input as the input query by providing voltage V3 on the wordline (WL) of the upper transistor and by providing voltage V4 on the wordline bar (W̅L̅). As illustrated, because V3 is more than Vt0, a current of I3 will flow through the upper transistor and because V4 is less than Vt7 no current will flow through the lower transistor. In other words, because V3 is more than Vt0 and because V4 is not more than Vt7, the upper transistor is turned on and the lower transistor is turned off. The current I3 is greater than the current I2 from example 806 because the voltage V3 is greater than voltage V2. This indicates that there is greater mismatch between the input value and the stored value in example 808 when compared to the mismatch in example 806. The current flow is represented as I3, such that the current on source line (SL) is approximately I3, which is approximately 9 times current I1.

Example 810 represents a logical input value of 4 and a logical stored value of 0. As discussed previously, the logical value of 0 is stored by setting the threshold voltage Vt of the upper transistor to Vt0 and the threshold voltage Vt of the lower transistor to Vt7. The logical value of 4 is input as the input query by providing voltage V4 on the wordline (WL) of the upper transistor and by providing voltage V3 on the wordline bar (W̅L̅). As illustrated, because V4 is more than Vt0, a current of I4 will flow through the upper transistor and because V3 is less than Vt7 no current will flow through the lower transistor. In other words, because V4 is more than Vt0 and because V3 is not more than Vt7, the upper transistor is turned on and the lower transistor is turned off. The current I4 is greater than the current I3 from example 808 because the voltage V4 is greater than voltage V3. This indicates that there is greater mismatch between the input value and the stored value in example 810 when compared to the mismatch in example 808. The current flow is represented as I4, such that the current on source line (SL) is approximately I4, which is approximately I6 times current I1.

Example 812 represents a logical input value of 5 and a logical stored value of 0. As discussed previously, the logical value of 0 is stored by setting the threshold voltage Vt of the upper transistor to Vt0 and the threshold voltage Vt of the lower transistor to Vt7. The logical value of 5 is input as the input query by providing voltage V5 on the wordline (WL) of the upper transistor and by providing voltage V2 on the wordline bar (W̅L̅). As illustrated, because V5 is more than Vt0, a current of I5 will flow through the upper transistor and because V2 is less than Vt7 no current will flow through the lower transistor. In other words, because V5 is more than Vt0 and because V2 is not more than Vt7, the upper transistor is turned on and the lower transistor is turned off. The current I5 is greater than the current I4 from example 810 because the voltage V5 is greater than voltage V4. This indicates that there is greater mismatch between the input value and the stored value in example 812 when compared to the mismatch in example 810. The current flow is represented as I5, such that the current on source line (SL) is approximately I5, which is approximately 25 times current I1.

Example 814 represents a logical input value of 6 and a logical stored value of 0. As discussed previously, the logical value of 0 is stored by setting the threshold voltage Vt of the upper transistor to Vt0 and the threshold voltage Vt of the lower transistor to Vt7. The logical value of 6 is input as the input query by providing voltage V6 on the wordline (WL) of the upper transistor and by providing voltage V1 on the wordline bar (W̅L̅). As illustrated, because V6 is more than Vt0, a current of I6 will flow through the upper transistor and because V1 is less than Vt7 no current will flow through the lower transistor. In other words, because V6 is more than Vt0 and because V1 is not more than Vt7, the upper transistor is turned on and the lower transistor is turned off. The current I6 is greater than the current I5 from example 812 because the voltage V6 is greater than voltage V5. This indicates that there is greater mismatch between the input value and the stored value in example 814 when compared to the mismatch in example 812. The current flow is represented as I6, such that the current on source line (SL) is approximately I6, which is approximately 36 times current I1.

Example 816 represents a logical input value of 7 and a logical stored value of 0. As discussed previously, the logical value of 0 is stored by setting the threshold voltage Vt of the upper transistor to Vt0 and the threshold voltage Vt of the lower transistor to Vt7. The logical value of 7 is input as the input query by providing voltage V7 on the wordline (WL) of the upper transistor and by providing voltage V0 on the wordline bar (W̅L̅). As illustrated, because V7 is more than Vt0, a current of I7 will flow through the upper transistor and because V0 is less than Vt7 no current will flow through the lower transistor. In other words, because V7 is more than Vt0 and because V0 is not more than Vt7, the upper transistor is turned on and the lower transistor is turned off. The current I7 is greater than the current I6 from example 814 because the voltage V7 is greater than voltage V6. This indicates that there is greater mismatch between the input value and the stored value in example 816 when compared to the mismatch in example 814. The current flow is represented as I7, such that the current on source line (SL) is approximately I7, which is approximately 49 times current I1.

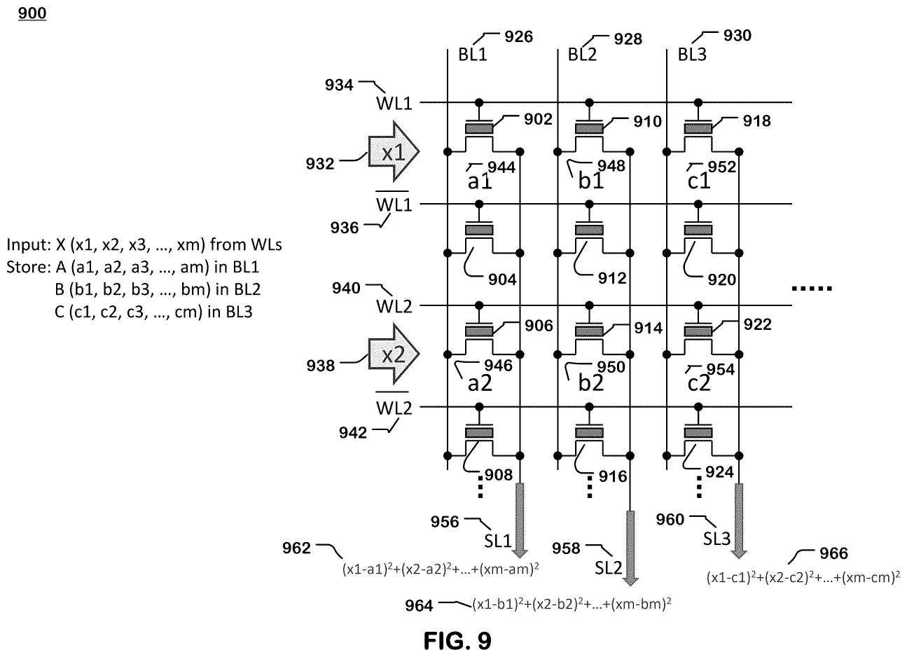

FIG. 9 illustrates a 2D NOR based in-memory-computing array 900 used to compare input data to stored data and to provide a current output that represents a Euclidean distance between the input data and the stored data.

The array 900 includes transistors 902, 904, 906 and 908 in a first NOR column, transistors 910, 912, 914 and 916 in a second NOR column and transistors 918, 920, 922 and 924 in a third NOR column. Bitline (BL1) 926 is connected to terminals of transistors 902, 904, 906 and 908 in the first NOR column, bitline (BL2) 928 is connected to terminals of transistors 910, 912, 914 and 916 in the second NOR column and bitline (BL3) 930 is connected to terminals of transistors 918, 920, 922 and 924 of the third NOR column.

Logical input value of x1 932 is provided as a 1-bit input query to a first pair of NOR rows on a pair of wordlines, wordline (WL) 934 and wordline bar (W̅L̅) 936, and logical input value of x2 938 is provided as an input query to a second pair of NOR rows on a pair of wordlines, wordline (WL) 940 and wordline bar (W̅L̅) 942. The providing of logical input values x1 932 and x2 938 to respective pairs of wordlines is according to the encoding illustrated in FIG. 5C. A stored value represented by a1 944 is stored by the transistor pair 902 and 904 and a stored value represented by a2 946 is stored by the transistor pair 906 and 908. A stored value represented by b1 948 is stored by the transistor pair 910 and 912 and a stored value represented by b2 950 is stored by the transistor pair 914 and 916. A stored value represented by c1 952 is stored by the transistor pair 918 and 920 and a stored value represented by c2 954 is stored by the transistor pair 922 and 924. The storage of each of stored values a1 944, a2 946, b1 948, b2 950, c1 952 and c2 954 in respective transistor pairs is according to the encoding illustrated in FIG. 5C.

An output current based on the stored logical values and the input query is provided from the first NOR column on source line (SL1) 956, an output current based on the stored logical values and the input query is provided from the second NOR column on source line (SL2) 958 and an output current based on the stored logical values and the input query is provided from the third NOR column on source line (SL3) 960. The output on SL1 956 can be represented by (x1−a1)²+(x2−a2)²+ . . . (xm−am)² (reference element 962) which can represent the Euclidean distance between the input x1, x2, . . . Xm and the stored data a1, a2, . . . am. The output on SL2 958 can be represented by (x1−b1)²+(x2—b2)²+ . . . (xm−bm)² (reference element 964) which can represent the Euclidean distance between the input x1, x2, . . . Xm and the stored data b1, b2, . . . bm. The output on SL3 960 can be represented by (x1−c1)²+(x2−c2)²+ . . . (xm−cm)² (reference element 966) which can represent the Euclidean distance between the input x1, x2, . . . Xm and the stored data c1, c2, . . . cm.

As illustrated and described above, logical values are stored in the bitline direction along columns and the input queries are received on the wordlines across the columns. By detecting the values on the different source lines, the Euclidean distance can be determined between the input query and the stored values. If there is a common source line (CSL) connecting the source lines, then the current detected by switching on different bitlines (e.g., switching the different bitlines in sequence) can be used to determine the Euclidean distance between the input query (e.g., x1) and data stored across columns (e.g., stored data a1 944, then stored data b1 948 and then stored data c1 952). If the array 900 has separate source lines (e.g., without a CSL) then the SL current can be detected in parallel. For example, the results of comparing x1 932 to a1 944, the results of comparing x1 932 to b1 948 and the results of comparing x1 932 to c1 952 can be provided in parallel on SL1 956, SL2 958 and SL3 960 by switching on Bl1 926, BL2 928 and BL3 930 at the same time.

These elements of FIG. 9 are just examples and a 2D NOR array having additional columns, rows and components can be implemented.

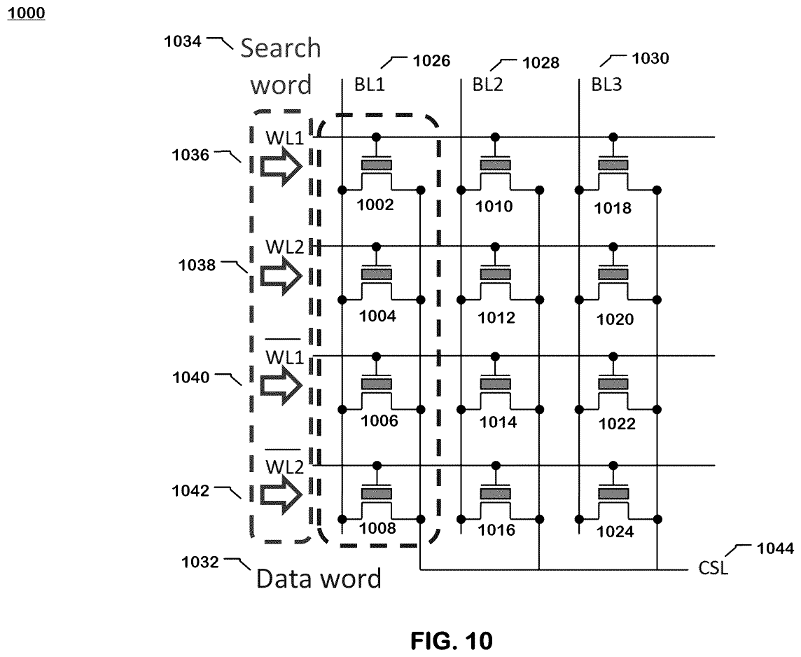

FIG. 10 illustrates a 2D NOR flash architecture 1000 according to which a search word is input on various wordlines to compare the search word to a stored data word that is stored in a column and according to which the Euclidean distance techniques can be applied to determine a distance between the search word and the stored data word.

Specifically, the 2D NOR flash architecture 1000 includes a first column of transistors 1002, 1004, 1006 and 1008 having terminals connected to bitline (BL1) 1026, a second column of transistors 1010, 1012, 1014 and 1016 having terminal connected to bitline (BL2) 1028 and a third column of transistors 1018, 1020, 1022 and 1024 having terminals connected to bitline (BL3) 1030. In this embodiment, a data word 1032 can be stored by the transistors 1002, 1004, 1006 and 1008 in the first column. In this example, transistor pair 1002 and 1006 can be used to store a first logical value of the data word 1032 and transistor pair 1004 and 1008 can be used to store a second logical value of the data word 1032. In other words, a 1-bit logical value can be stored by transistor pair 1002 and 1006 and another 1-bit logical value can be stored by transistor pair 1004 and 1008.

A 1-bit input query can be provided to transistor pair 1002 and 1006 representing a portion of a search word 1034 and a 1-bit input query can be provided to transistor pair 1004 and 1008 representing another portion of search word 1034. For example, an entire input query or search word 1034 can be received on wordline (WL1) 1036, wordline (WL2) 1038, wordline bar (WL1) 1040 and wordline bar (WL2) 1042. The providing of logical input values to respective pairs of wordlines (e.g., wordline (WL1) 1036 and wordline bar (WL1) line 1040) can be done according to the encoding illustrated in FIG. 5C. The result of comparing the search word 1034 to the data word 1032 provides a current on the common source line (CSL) 1044 that can be used to determine the Euclidean distance between the search word 1034 and the data word 1032, assuming bitline (BL1) 1026 is switched on and bitline (BL2) 1028 and bitline (BL3) 1030 are switched off, using the techniques described herein. The wordline and the wordline bar can be on adjacent rows, for example, as illustrated in FIG. 9, or they can be on non-adjacent rows, as illustrated in FIG. 10. In the examples provided throughout this document, wordline and wordline bar can be moved so that they are adjacent to one another or so that they are not adjacent to one another.

These elements of FIG. 10 are just examples and a 2D NOR flash architecture having additional columns, rows and other components can be implemented.

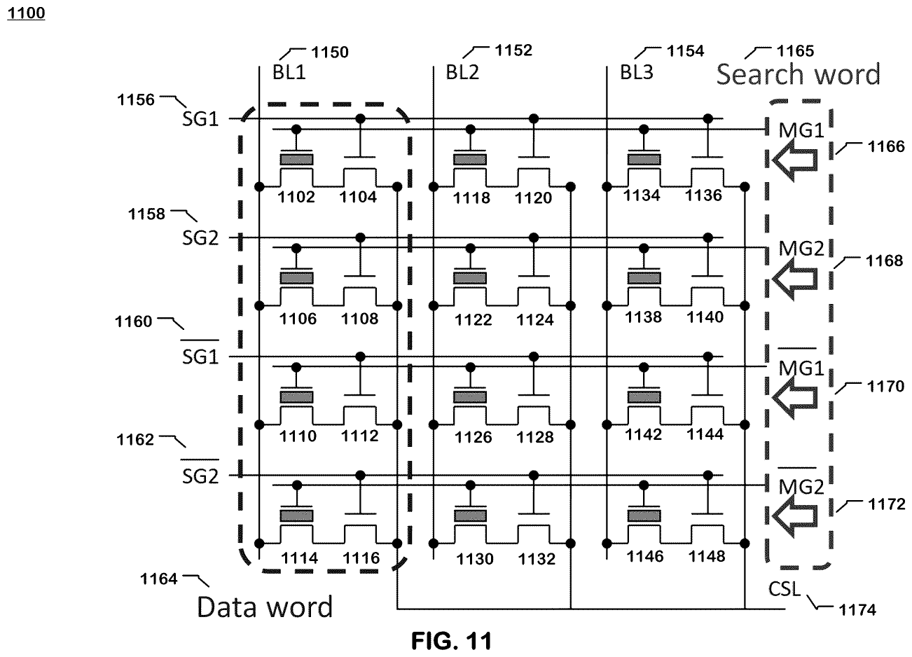

FIG. 11 illustrates a 2T-NOR flash architecture 1100 according to which a search word is input on various MG lines to compare the search word to a stored data word that is stored in a column and according to which the Euclidean distance techniques can be applied to determine a distance between the search word and the stored data word.

Specifically, the 2T-NOR flash architecture 1100 includes a first column of a transistor pair including transistors 1102 and 1104, a transistor pair including transistors 1106 and 1108, a transistor pair including transistors 1110 and 1112 and a transistor pair including transistors 1114 and 1116. The first column of transistors is connected to bitline (BL1) 1150.

The 2T-NOR flash architecture 1100 includes a second column of a transistor pair including transistors 1118 and 1120, a transistor pair including transistors 1122 and 1124, a transistor pair including transistors 1126 and 1128 and a transistor pair including transistors 1130 and 1132. The second column of transistors is connected to bitline (BL2) 1152.

The 2T-NOR flash architecture 1100 also includes a third column of a transistor pair including transistors 1134 and 1136, a transistor pair including transistors 1138 and 1140, a transistor pair including transistors 1142 and 1144 and a transistor pair including transistors 1146 and 1148. The second column of transistors is connected to bitline (BL3) 1154.

A select gate (SG1) line 1156 is connected to a row of transistors 1104, 1120 and 1136, select gate (SG2) line 1158 is connected to a row of transistors 1108, 1124 and 1140, select gate bar (S̅G̅1̅) line 1160 is connected to a row of transistors 1112, 1128 and 1144 and select gate bar (S̅G̅2̅) line 1162 is connected to a row of transistors 1116, 1132 and 1148. Select gate (SG1) line 1156, select gate (SG2) line 1158, select gate bar (S̅G̅1̅) line 1160 and select gate bar (S̅G̅2̅) line 1162 are used to enable or disable searching on their corresponding rows by turning the transistors connected thereto on or off.

A main gate (MG1) line 1166 is connected to a row of transistors 1102, 1118 and 1134, main gate (MG2) line 1168 is connected to a row of transistors 1106, 1122 and 1138, main gate bar (M̅G̅1̅) line 1170 is connected to a row of transistors 1110, 1126 and 1142 and main gate bar (M̅G̅2̅) line 1172 is connected to a row of transistors 1114, 1130 and 1146. Main gate (MG1) line 1166, main gate (MG2) line 1168, main gate bar (M̅G̅1̅) line 1170 and main gate bar (M̅G̅2̅) line 1172 are used to provide a search word 1165 to transistors of one or more selected columns. For example, data word 1164 can be stored in the first column (e.g., stored in transistors 1102, 1106, 1110 and 1114). The select gate and select gate bar lines can be turned on to enable searching on each of the four rows. Similar to FIGS. 9 and 10, a 1-bit input query can be provided to transistor pair 1102 and 1110 representing a portion of search word 1165 and a 1-bit input query can be provided to transistor pair 1106 and 1114 representing another portion of search word 1165. One logical value of search word 1165 can be provided on main gate (MG1) line 1166 and main gate bar (M̅G̅1̅) line 1170 and another logical value of search word 1165 can be provided on main gate (MG2) line 1168 and main gate bar (M̅G̅2̅) line 1172. The providing of logical input values to respective pairs of main gate lines (e.g., main gate line (MG1) 1166 and main gate bar (M̅G̅1̅) line 1170) can be done according to the encoding illustrated in FIG. 5C. Other configurations for inputting logical values can be implemented. A current output on current source line (CSL) 1174 can be used to determine the Euclidean distance between the search word 1165 and the data word 1164, assuming bitline (BL1) 1150 is switched on and bitline (BL2) 1152 and bitline (BL3) 1154 are switched off, using techniques described herein.

These elements of FIG. 11 are just examples and a 2T NOR flash architecture having additional columns, rows and other components can be implemented.

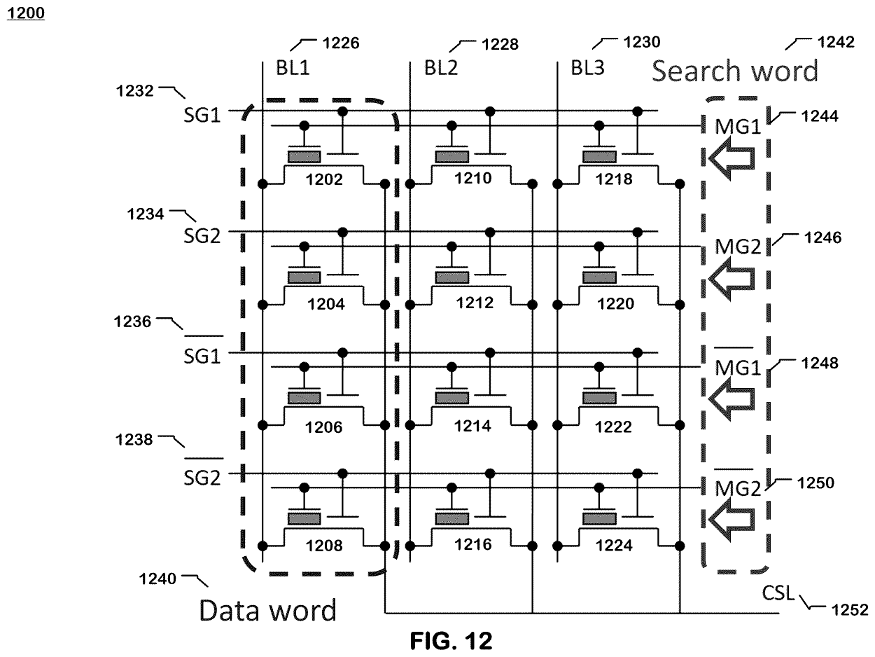

FIG. 12 illustrates a split-gate NOR flash architecture 1200 according to which a search word is input on various MG lines to compare the search word to a stored data word that is stored in a column and according to which the Euclidean distance techniques can be applied to determine a distance between the search word and the stored data word.

Specifically, the split-gate NOR flash architecture 1200 includes a first column of split-gate transistors 1202, 1204, 1206 and 1208 connected to bitline (BL1) 1226, a second column of split-gate transistors 1210, 1212, 1214 and 1216 connected to bitline (BL2) 1228 and a third column of split-gate transistors 1218, 1220, 1222 and 1224 connected to bitline (BL3) 1230. Each of split-gate transistors 1202, 1204, 1206, 1208, 1210, 1212, 1214, 1216, 1218, 1220, 1222 and 1224 includes two gates (e.g., a main gate such as a floating gate for data storage and a select gate).

A select gate (SG1) line 1232 is connected to select gates of a row of transistors 1202, 1210 and 1218, select gate (SG2) line 1234 is connected to select gates of a row of transistors 1204, 1212 and 1220, select gate bar (S̅G̅1̅) line 1236 is connected to select gates of a row of transistors 1206, 1214 and 1222 and select gate bar (S̅G̅2̅) line 1238 is connected to select gates of a row of transistors 1208, 1216 and 1224. Select gate (SG1) line 1232, select gate (SG2) line 1234, select gate bar (S̅G̅1̅) line 1236 and select gate bar (S̅G̅2̅) line 1238 are used to enable or disable searching on their corresponding rows by turning the select gates of the transistors connected thereto on or off.

A main gate (MG1) line 1244 is connected to main gates of a row of transistors 1202, 1210 and 1218, main gate (MG2) line 1246 is connected to main gates of a row of transistors 1204, 1212 and 1220, main gate bar (M̅G̅1̅) line 1248 is connected to main gates of a row of transistors 1206, 1214 and 1222 and main gate bar (M̅G̅2̅) line 1250 is connected to main gates of a row of transistors 1208, 1216 and 1224. Main gate (MG1) line 1244, main gate (MG2) line 1246, main gate bar (M̅G̅1̅) line 1248 and main gate bar (M̅G̅2̅) line 1250 are used to provide a search word 1242 to transistors of one or more selected columns. For example, data word 1240 can be stored in the first column (e.g., stored in transistors 1202, 1204, 1206 and 1208). The select gate and select gate bar lines can be turned on to enable searching on each of the four rows. Similar to FIGS. 9-11, a 1-bit input query can be provided to transistor pair 1202 and 1206 representing a portion of search word 1242 and a 1-bit input query can be provided to transistor pair 1204 and 1208 representing another portion of search word 1242. One logical value of search word 1242 can be provided on main gate (MG1) line 1244 and main gate bar (M̅G̅1̅) line 1248 and another logical value of search word 1242 can be provided on main gate (MG2) line 1246 and main gate bar (M̅G̅2̅) line 1250. The providing of logical input values to respective pairs of main gate lines (e.g., main gate line (MG1) 1244 and main gate bar (M̅G̅1̅) line 1248) can be done according to the encoding illustrated in FIG. 5C. Other configurations for inputting logical values can be implemented. A current output on current source line (CSL) 1252 can be used to determine the Euclidean distance between the search word 1242 and the data word 1240, assuming bitline (BL1) 1226 is switched on and bitline (BL2) 1228 and bitline (BL3) 1230 are switched off, using techniques described herein.

These elements of FIG. 12 are just examples and a split-gate NOR flash architecture having additional columns, rows and other components can be implemented.

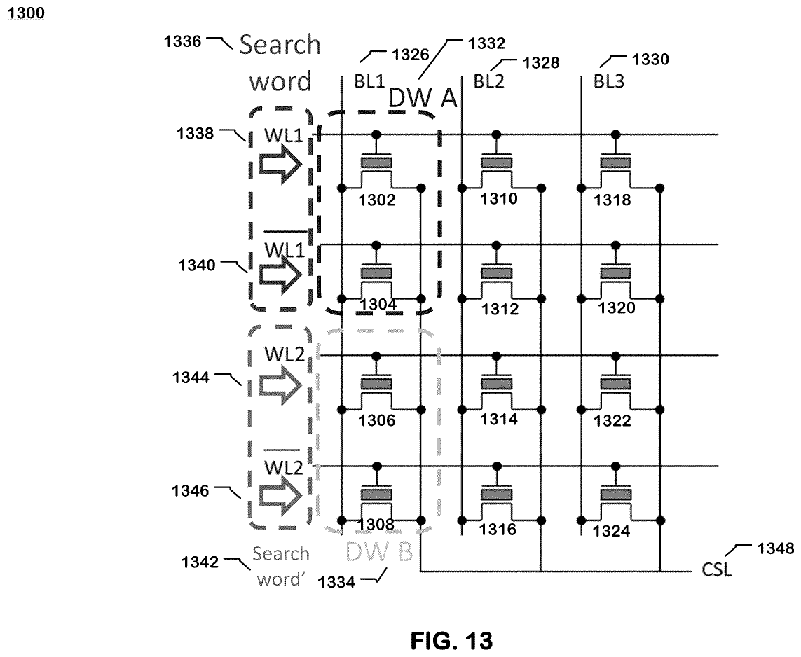

FIG. 13 illustrates a 2D NOR flash architecture 1300 according to which two search words are input on various wordlines to compare the two search words to two stored data words stored in a column and according to which the Euclidean distance techniques can be applied to determine a distance between the search words and the stored data words.

Specifically, the 2D NOR flash architecture 1300 includes a first column of transistors 1302, 1304, 1306 and 1308 having terminals connected to bitline (BL1) 1326, a second column of transistors 1310,1312, 1314 and 1316 having terminals connected to bitline (BL2) 1328 and a third column of transistors 1318, 1320, 1322 and 1324 having terminals connected to bitline (BL3) 1330. In this embodiment, a data word (DWA) 1332 can be stored by transistors 1302 and 1304 and data word (DWB) 1334 can be stored by transistors 1306 and 1308 in the first column.

An input query or search word 1336 can be received on wordline (WL1) 1338 and wordline bar (W̅L̅1̅) 1340, and an input query or search word′ 1342 can be received on wordline (WL2) 1344 and wordline bar (W̅L̅2̅) 1346. Similar to FIGS. 9-12, the search word 1336 can represent a 1-bit input query (logical value) that can be provided to transistor pair 1302 and 1304 and the search word′ 1342 can represent a 1-bit input query (logical value) that can be provided to transistor pair 1306 and 1308. Providing of the logical input values, which can represent the 1-bit input query, to respective pairs of wordlines (e.g., wordline (WL1) 1338 and wordline bar (W̅L̅1̅) 1340) can be done according to the encoding illustrated in FIG. 5C.

The result of comparing the search word 1336 to the data word (DWA) 1332 provides a current on the common source line (CSL) 1348 that can be used to determine the Euclidean distance between the search word 1336 and the data word (DWA) 1332 using the techniques described herein and the result of comparing the search word′ 1342 to the data word (DWB) 1334 provides a current on the common source line (CSL) 1348 that can be used to determine the Euclidean distance between the search word′ 1342 and the data word (DWB) 1334 using the techniques described herein. In this example one search word (e.g., search word 1336) can be compared at a time to a data word (e.g., data word (DWA) 1332). Search word 1336 can be input for searching at a different time than search word′ 1342, so that different search words can be used for searching at different times. For example, search word 1336 can be received on wordline (WL1) 1338 and wordline bar (W̅L̅1̅) 1340, while wordline (WL2) 1344 and wordline bar (W̅L̅2̅) 1345 are turned off, thus enabling searching only based on search word 1336. For another example, search word′ 1342 can be received on wordline (WL2) 1344 and wordline bar (W̅L̅2̅) 1345, while wordline (WL1) 1338 and wordline bar (W̅L̅1̅) 1340 are turned off, thus enabling searching only based on search word′ 1342.

These elements of FIG. 13 are just examples and a 2D NOR flash architecture having additional columns, rows and other components can be implemented.

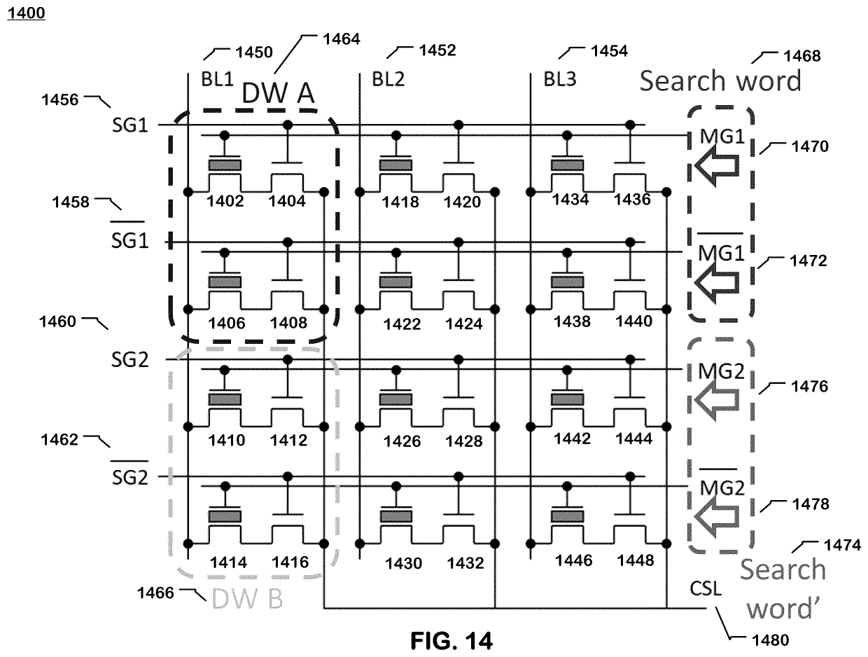

FIG. 14 illustrates a 2T-NOR flash architecture 1400 according to which two search words are input on various wordlines to compare the two search words to two stored data words stored in a column and according to which the Euclidean distance techniques can be applied to determine a distance between the search words and the stored data words.

Specifically, the 2T-NOR flash architecture 1400 includes a first column of a transistor pair including transistors 1402 and 1404, a transistor pair including transistors 1406 and 1408, a transistor pair including transistors 1410 and 1412 and a transistor pair including transistors 1414 and 1416. The first column of transistors is connected to bitline (BL1) 1450.

The 2T-NOR flash architecture 1400 includes a second column of a transistor pair including transistors 1418 and 1420, a transistor pair including transistors 1422 and 1424, a transistor pair including transistors 1426 and 1428 and a transistor pair including transistors 1430 and 1432. The second column of transistors is connected to bitline (BL2) 1452.

The 2T-NOR flash architecture 1400 also includes a third column of a transistor pair including transistors 1434 and 1436, a transistor pair including transistors 1438 and 1440, a transistor pair including transistors 1442 and 1444 and a transistor pair including transistors 1446 and 1448. The second column of transistors is connected to bitline (BL3) 1454.

A select gate (SG1) line 1456 is connected to a row of transistors 1404, 1420 and 1436, select gate bar (S̅G̅1̅) line 1458 is connected to a row of transistors 1408, 1424 and 1440, select gate (SG2) line 1460 is connected to a row of transistors 1412, 1428 and 1444 and select gate bar (S̅G̅2̅) line 1462 is connected to a row of transistors 1416, 1432 and 1448. Select gate (SG1) line 1456, select gate bar (S̅G̅1̅) line 1458, select gate bar (S̅G̅1̅) line 1460 and select gate bar (S̅G̅2̅) line 1462 are used to enable or disable searching on their corresponding rows by turning the transistors connected thereto on or off.

A main gate (MG1) line 1470 is connected to a row of transistors 1402, 1418 and 1434, main gate bar (M̅G̅1̅) line 1472 is connected to a row of transistors 1406, 1422 and 1438, main gate (MG2) line 1476 is connected to a row of transistors 1410, 1426 and 1442 and main gate bar (M̅G̅2̅) line 1478 is connected to a row of transistors 1414, 1430 and 1446. Main gate (MG1) line 1470 and main gate bar (M̅G̅1̅) line 1472 are used to provide search word 1468 to transistors of one or more selected rows and columns, and main gate (MG2) line 1476 and main gate bar (M̅G̅2̅) line 1478 are used to provide a search word′ 1474 to transistors to one or more selected rows and columns. Similar to FIGS. 9-13, the search word 1468 can represent a 1-bit input query (logical value) that can be provided to transistor pair 1402 and 1406 and the search word′ 1474 can represent a 1-bit input query (logical value) that can be provided to transistor pair 1410 and 1414. The providing of the logical input values, which can represent the 1-bit input query, to respective pairs of wordlines (e.g., wordline (WL1) 1470 and wordline bar (W̅L̅1̅) 1472) can be done according to the encoding illustrated in FIG. 5C.

For example, data word (DWA) 1464 can be stored in the first and second rows of the first column (e.g., stored in transistors 1402 and 1406) and data word (DWB) 1466 can be stored in the third and fourth rows of the first column (e.g., stored in transistors 1410 and 1414). The select gate and select gate bar lines can be turned on to enable searching on each of the four rows. Search word 1468 can be provided on main gate (MG1) line 1470 and main gate bar (M̅G̅1̅) line 1472, and search word′ 1474 can be provided on main gate (MG2) line 1476 and main gate bar (M̅G̅2̅) line 1478. A current output on common source line (CSL) 1480 can be used to determine the Euclidean distance between the search word 1468 and the data word (DWA) 1464 and between the search word′ 1474 and the data word (DWB) 1466 using techniques described herein. Search word 1468 can be input for searching at a different time than search word′ 1474, so that different search words can be used for searching at different times.

These elements of FIG. 14 are just examples and a 2T NOR flash architecture having additional columns, rows and other components can be implemented.

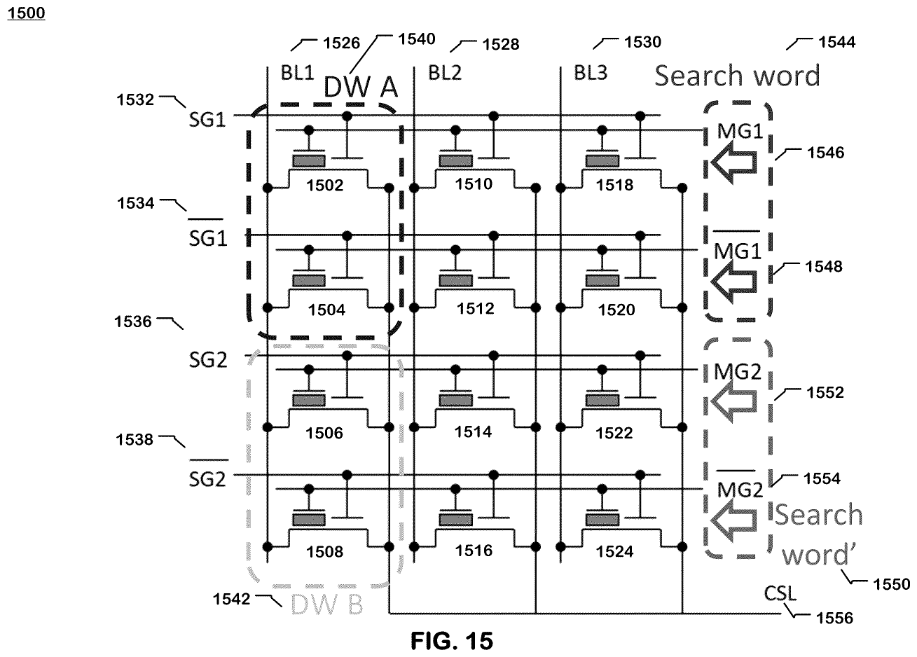

FIG. 15 illustrates a split-gate NOR flash architecture 1500 according to which two search words are input on various wordlines to compare the two search words to two stored data words stored in a column and according to which the Euclidean distance techniques can be applied to determine a distance between the search words and the stored data words.

Specifically, the split-gate NOR flash architecture 1500 includes a first column of split-gate transistors 1502, 1504, 1506 and 1508 connected to bitline (BL1) 1526, a second column of split-gate transistor 1510, 1512, 1514 and 1516 connected to bitline (BL2) 1528 and a third column of split-gate transistors 1518, 1520, 1522 and 1524 connected to bitline (BL3) 1530. Each of split-gate transistors 1502, 1504, 1506, 1508, 1510, 1512, 1514, 1516, 1518, 1520, 1522 and 1524 includes two gates (e.g., a main gate such as a floating gate for data storage and a select gate).

A select gate (SG1) line 1532 is connected to select gates of a row of transistors 1502, 1510 and 1518, select gate bar (S̅G̅1̅) line 1534 is connected to select gates of a row of transistors 1504, 1512 and 1520, select gate (SG2) line 1536 is connected to select gates of a row of transistors 1506, 1514 and 1522 and select gate bar (S̅G̅2̅) line 1538 is connected to select gates of a row of transistors 1508, 1516 and 1524. Select gate (SG1) line 1532, select gate bar (S̅G̅1̅) line 1534, select gate (SG2) line 1536, select gate bar (S̅G̅2̅) line 1538 are used to enable or disable searching on their corresponding rows by turning the select gates of the transistors connected thereto on or off.

A main gate (MG1) line 1546 is connected to main gates of a row of transistors 1502, 1150 and 1518, main gate bar (M̅G̅1̅) line 1548 is connected to main gates of a row of transistors 1504, 1512 and 1520, main gate (MG2) line 1552 is connected to main gates of a row of transistors 1506, 1514 and 1522 and main gate bar (M̅G̅2̅) line 1554 is connected to main gates of a row of transistors 1508, 1516 and 1524. Main gate (MG1) line 1546 and main gate bar (M̅G̅1̅) line 1548 are used to provide search word 1544 to transistors of one or more selected columns and main gate (MG2) line 1552 and main gate bar (M̅G̅2̅) line 1554 are used to provide a search word′ 1550 to transistors of one or more selected columns. For example, data word (DWA) 1540 can be stored in the first and second rows of the first column (e.g., stored in transistors 1502 and 1204) and data word (DWB) 1542 can be stored in the third and fourth rows of the first column (e.g., stored in transistors 1506 and 1508). The select gate and select gate bar lines can be turned on to enable searching on each of the four rows. Similar to FIGS. 9-14, a 1-bit input query can be provided to transistor pair 1502 and 1504 representing search word 1546 and a 1-bit input query can be provided to transistor pair 1506 and 1508 representing search word′ 1550. A logical value of search word 1544 can be provided on main gate (MG1) line 1546 and main gate bar (M̅G̅1̅) line 1548 and a logical value of search word 1550 can be proved on main gate (MG2) line 1552 and main gate bar (M̅G̅2̅) line 1554. The providing of logical input values to respective pairs of main gate lines (e.g., main gate line (MG1) 1546 and main gate bar (M̅G̅1̅) line 1548) can be done according to the encoding illustrated in FIG. 5C. A current output on common source line (CSL) 1556 can be used to determine the Euclidean distance between the search word 1544 and the data word (DWA) 1540 using techniques described herein and to determine the Euclidean distance between the search word′ 1550 and the data word (DWB) 1542 using techniques described herein. Search word 1544 can be input for searching at a different time than search word′ 1550, so that different search words can be used for searching at different times. For example, to search for search word 1544, (MG2) line 1552 and main gate bar (M̅G̅2̅) line 1554 are turned off. For another example, to search for search word′ 1550, main gate (MG1) line 1546 and main gate bar (M̅G̅1̅) line 1548 are turned off.

These elements of FIG. 15 are just examples and a split-gate NOR flash architecture having additional columns, rows and other components can be implemented.

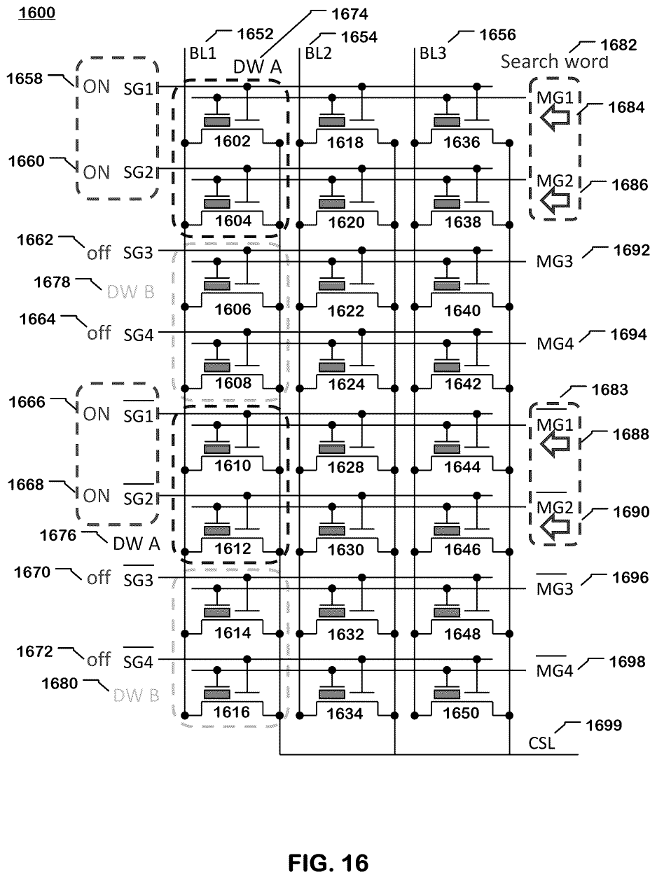

FIG. 16 illustrates a split-gate NOR flash architecture 1600 according to which two search words are input on various wordlines to compare the two search words to two stored data words stored in a column, according to which various rows in the NOR flash architecture are disabled for searching purposes and according to which the Euclidean distance techniques can be applied to determine a distance between the search words and the stored data words.

Specifically, the split-gate NOR flash architecture 1600 includes a first column of split-gate transistors 1602, 1604, 1606, 1608, 1610, 1612, 1614 and 1616 connected to bitline (BL1) 1652, a second column of split-gate transistors 1618, 1620, 1622, 1624, 1628, 1630, 1632 and 1634 connected to bitline (BL2) 1654 and a third column of split-gate transistors 1636, 1638, 1640, 1642, 1644, 1646, 1648 and 1650 connected to bitline (BL3) 1656. Each of split-gate transistors 1602, 1604, 1606, 1608, 1610, 1612, 1614, 1616, 1618, 1620, 1622, 1624, 1628, 1630, 1632, 1634, 1636, 1638, 1640, 1642, 1644, 1646, 1648 and 1650 includes two gates (e.g., a main gate such as a floating gate for data storage and a select gate).

A select gate (SG1) line 1658 is connected to select gates of a row of transistors 1602, 1618 and 1636, select gate (SG2) line 1660 is connected to select gates of a row of transistors 1604, 1620 and 1638, select gate (SG3) line 1662 is connected to select gates of a row of transistors 1606, 1622 and 1640, select gate (SG4) line 1664 is connected to select gates of a row of transistors 1608, 1624 and 1642, select gate bar (S̅G̅1̅) line 1666 is connected to select gates of a row of transistors 1610, 1628 and 1644, select gate bar (S̅G̅2̅) line 1668 is connected to select gates of a row of transistors 1612, 1630 and 1646, select gate bar (S̅G̅3̅) line 1670 is connected to select gates of a row of transistors 1614, 1632 and 1648 and select gate bar (S̅G̅4̅) line 1672 is connected to select gates of a row of transistors 1616, 1634 and 1650.

A first portion of a data word including data word (DWA) 1674 is stored in the first and second rows of the first column in the main gates of transistors 1602 and 1604 and a second portion of the data word including data word (DWA) 1676 is stored in the fifth and six rows of the first column in the main gates of transistors 1610 and 1612. A first portion of a data word including data word (DWB) 1678 is stored in the third and fourth rows of the first column in the main gates of transistors 1606 and 1608 and a second portion of the data word including data word (DWB) 1680 is stored in the seventh and eights rows of the first column in the main gates of transistors 1614 and 1616.

In this example, select gate (SG1) line 1658 and select gate (SG2) line 1660 are turned on to allow a first portion of a search word including search word 1682 provided on main gate (MG1) line 1684 and main gate (MG2) line 1686 to be compared to data word (DWA) 1674. Further, select gate bar (S̅G̅1̅) line 1666 and select gate bar (S̅G̅2̅) line 1668 are turned on to allow a second portion of the search word including search word 1683 provided on main gate bar (M̅G̅1̅) line 1688 and main gate bar (M̅G̅1̅) line 1690 to be compared to data word (DWA) 1676.

Further, in this example, select gate (SG3) line 1662 and select gate (SG4) line 1664 are turned off so that data provided on main gate (MG3) line 1692 and main gate (MG4) line 1694 is not compared to data word (DWB) 1678. Further, select gate bar (S̅G̅3̅) line 1670 and select gate bar (S̅G̅4̅) line 1672 are turned off so that data provided on main gate bar (MG3) line 1696 and main gate bar (M̅G̅4̅) line 1698 is not compared to data word (DWB) 1680.

Similar to FIGS. 9-15, a 1-bit input query can be provided to transistor pair 1602 and 1610 representing a portion of search words 1682 and 1683, and a 1-bit input query can be provided to transistor pair 1604 and 1612 representing other portions of search words 1682 and 1683. As an alternate example, the concept of which can be implemented in the other memory diagrams of FIGS. 9-15, a 1-bit input query can be provided to transistor pair 1602 and 1604 representing a search word 1682, and a 1-bit input query can be provided to transistor pair 1610 and 1612 representing search word 1683. The providing of logical input values to respective pairs of main gate lines can be done according to the encoding illustrated in FIG. 5C.

The output current resulting from the comparison of search word 1682 to data word (DWA) 1674 and resulting from the comparison of search word 1683 to data word (DWA) 1676 is provided on common source line (CSL) 1699 and can be used to determine the Euclidean distance between the search words 1682 and 1683 and the data words (DWA) 1674 and 1676, specifically the Euclidean distance between the search word 1682 and the data word (DWA) 1674 summed with the Euclidean distance between the search word 1683 and the data word (DWA) 1676.

Using this architecture, more than one data word can be stored using a single bitline (BL) (e.g., can be stored in a single column). The SG and SG bar lines and the MG and MG bar lines of the unused rows can be turned off (e.g., biased at 0V for unused SG and SG bar lines and biased at less than or equal to 0V for unused MG and MG bar lines).

These elements of FIG. 16 are just examples and a split-gate NOR flash architecture having additional columns, rows and other components can be implemented.

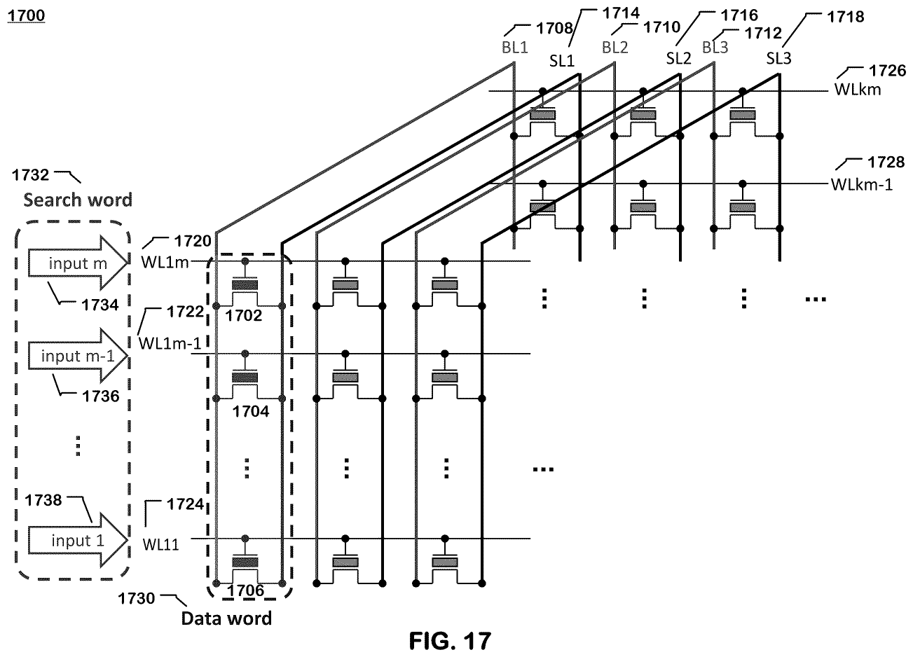

FIG. 17 illustrates a 3D NOR flash architecture 1700 according to which a search word is input on various wordlines of a column of transistors of a block to compare the search word to a stored data word that is stored in a column of transistors of the block and according to which the Euclidean distance techniques can be applied to determine a distance between the search word and the stored data word.

Specifically, the 3D NOR flash architecture 1700 includes a block of columns, where transistors 1702, 1704 and 1706 are used to store data word 1730 and further includes bitline (BL1) 1708, bitline (BL2) 1710, bitline (BL3) 1712, source line (SL1) 1714, source line (SL2) 1716, source line (SL3) 1718, wordline (WL1m) 1720, wordline (WL1m−1) 1722, wordline (WL11) 1724, wordline (WLkm) 1726 and wordline (WLkm−1) 1728. Search word 1732 can be provided as input m 1734, input m−1 1736 and input 1 1738 on wordline (WL1m) 1720, wordline (WL1m−1) 1722, wordline (WL11) 1724, respectively. The same or similar concepts described above with respect to FIGS. 10-16 can apply here to FIG. 17 regarding the storing data to represent logical values and the searching using an input query to represent logical values.

According to this implementation, the input query (e.g., the search word 1732) is provided on wordlines on a single block, where one data word 1730 is stored using one bitline (BL1) 1708 of one block, and where block select transistors of the unused data blocks sharing the same bitline are turned off or the wordlines for the unused blocks are turned off.

These elements of FIG. 17 are just examples and a 3D NOR flash architecture having additional columns, rows and other components can be implemented.

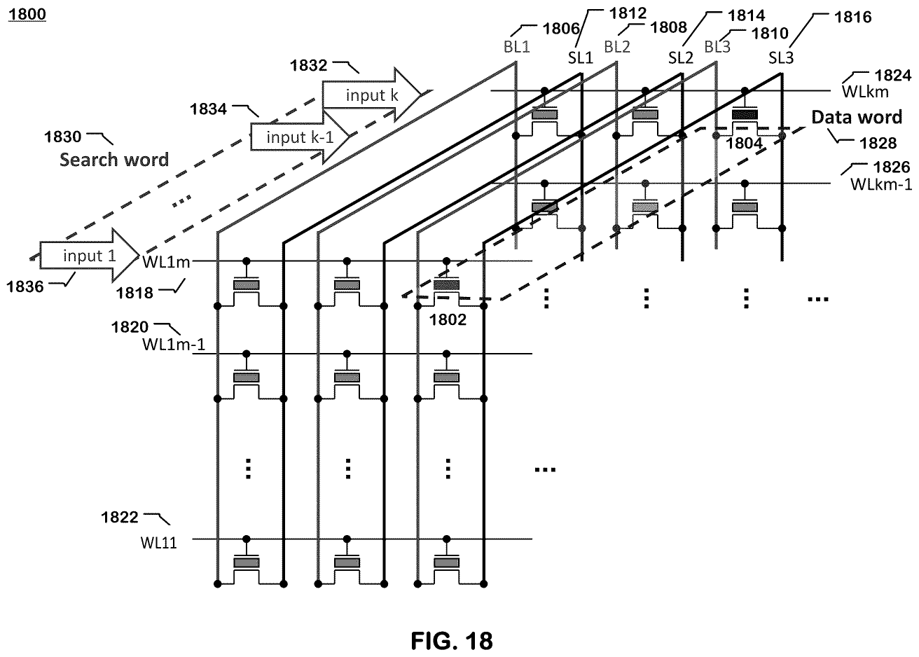

FIG. 18 illustrates a 3D NOR flash architecture according to which a search word is input on one wordline in each of different blocks to compare the search word to a stored data word that is stored in one bitline in each of different blocks and according to which the Euclidean distance techniques can be applied to determine a distance between the search word and the stored data word.

Specifically, the 3D NOR flash architecture 1800 includes multiple blocks in which transistors 1802 and 1804, which span across multiple blocks and are used to store data word 1828 and further includes bitline (BL1) 1806, bitline (BL2) 1808, bitline (BL3) 1810, source line (SL1) 1812, source line (SL2) 1814, source line (SL3) 1816, wordline (WL1m) 1818, wordline (WL1m−1) 1820, wordline (WL11) 1822, wordline (WLkm) 1824 and wordline (WLkm−1) 1826. Search word 1830 can be provided as input k 1832, input k−1 1834 and input 1 1836 on wordline (WLKm) 1824 through wordline WL1m 1818. The same or similar concepts described above with respect to FIGS. 10-16 can apply here to FIG. 18 regarding the storing data to represent logical values and the searching using an input query to represent logical values.

According to this implementation, the input query (e.g., the search word 1830) is provided on one wordline in each of different blocks, where one data word 1828 is stored using one bitline (BL3) 1810 of different blocks. The wordlines of unused layers can be turned off and the wordlines for any unused blocks can be turned off.

These elements of FIG. 18 are just examples and a 3D NOR flash architecture having additional columns, rows and other components can be implemented.

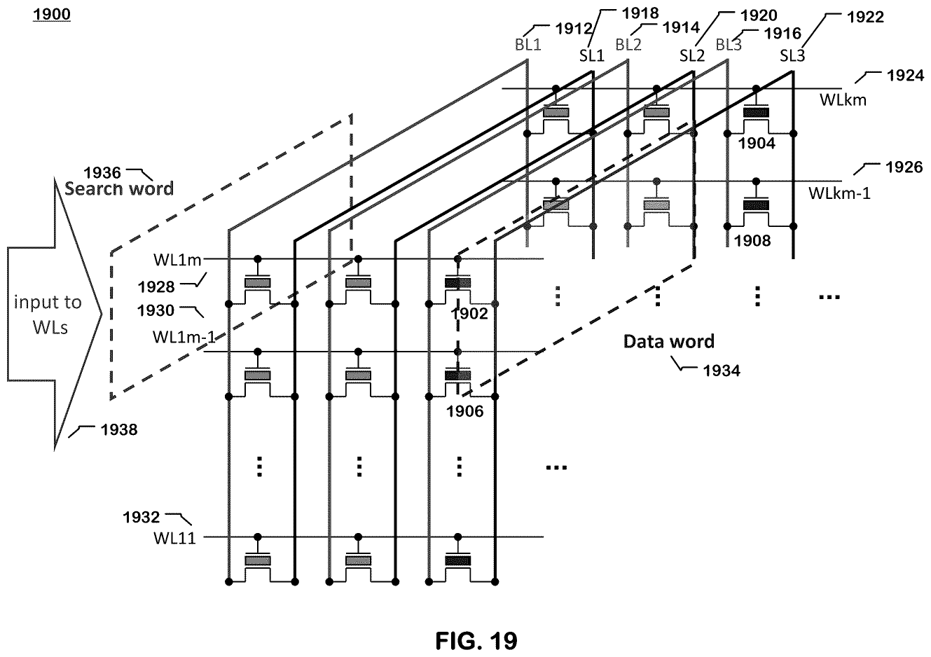

FIG. 19 illustrates a 3D NOR flash architecture according to which a search word is input on multiple wordlines in each of different blocks to compare the search word to a stored data word that is stored in multiple bitlines in each of different blocks and according to which the Euclidean distance techniques can be applied to determine a distance between the search word and the stored data word.

Specifically, the 3D NOR flash architecture 1900 includes multiple blocks and layers in which transistors 1902, 1904, 1906 and 1908, which collectively span across multiple blocks and layers are used to store data word 1934 and further includes bitline (BL1) 1912, bitline (BL2) 1914, bitline (BL3) 1916, source line (SL1) 1918, source line (SL2) 1920, source line (SL3) 1922, wordline (WL1m) 1928, wordline (WL1m−1) 1930, wordline (WL11) 1932, wordline (WLkm) 1924 and wordline (WLkm−1) 1926. Search word 1936 is provided as an input to wordlines 1938 on wordlines from multiple layers of multiple blocks. The same or similar concepts described above with respect to FIGS. 10-16 can apply here to FIG. 19 regarding the storing data to represent logical values and the searching using an input query to represent logical values.

According to this implementation, the input query (e.g., the search word 1936) can be provided on multiple wordlines of multipole blocks, where one data word 1934 can be stored using one bitline for each of different blocks, where the wordlines of the unused layers can be turned off and the wordlines of the used clocks can be turned off.

These elements of FIG. 19 are just examples and a 3D NOR flash architecture having additional columns, rows and other components can be implemented.

The techniques describe herein can be used in various types of memory that implement, at least, MOSFET transistors, FinFET transistors and TFET transistors. Further, these techniques can be implemented in, at least, floating gate flash memory, silicon-oxide-nitride-oxide-silicon (SONOS) flash memory, floating dot flash memory, NOR flash memory, NAND flash memory, split-gate NOR flash memory, 2T NOR flash memory, and two-transistor zero-capacitor (2TOC) devices.

FIG. 20 is a simplified block diagram of a system comprising memory configured for IMS using a sequence of search words and implementing the various Euclidean distance techniques described herein.

FIG. 20 is a simplified chip block diagram of an embodiment of a memory system 2100 including a memory array 2160, such as a 2D NOR flash memory or a 3D NOR flash memory. The memory system 2100 is configured for memory operations, including for NOR flash embodiments page program, program, read, erase, or other operations, and for IMS operations. Portions of memory system 2100 can be implemented on a single integrated circuit chip, on a multichip module, or on a plurality of chips configured as suits a particular need and other portions of memory system 2100 can be implemented separately, such as configuration circuitry 2102.

The memory system 2100 in this example includes a controller 2110, that includes control circuits such as state machines and other logic circuits, for memory operations in a memory mode, and IMS operations in an IMS mode including a sequencer supporting sequential match operations as described herein. The controller 2110 can include or have access to control registers storing parameters of operation of the device, including a threshold register 2111 storing a parameter setting other values, such as ΔV, etc., as described above. The controller 2110 can be used to implement the Euclidean distance techniques described herein.

The memory array 2160 can comprise floating gate memory cells or dielectric charge trapping memory cells configured to store multiple bits per cell, by the establishment of multiple program levels that correspond to amounts of charge stored, which in turn establish memory cell threshold voltages Vt. In various embodiments, the memory system 2100 may have single-level cells (SLC), or multiple-level cells storing more than one bit per cell (e.g., MLC, TLC or XLC) or any of the other memory structures described herein.

In other examples, the memory cells may comprise programmable resistance memory cells, ferro electric memory cells, phase change memory cells, and other types of nonvolatile and volatile memory cell technologies.

The memory system 2100 includes a set of bit lines 2165 coupled to corresponding sets of memory cells in the memory array 2160.

A set of word lines 2145 is coupled to gates of the memory cells in the memory array 2160. A word line decoder 2140 and a search word buffer 2141 are coupled to a set of word lines 2145, and configured to drive operational voltages for read and write operations in response to address decoding, and for IMS operations in response to input search words in the search word buffer 2141.

The page buffer 2170 is connected to bit lines 2165. The page buffer 2170 is coupled to a cache 2190. The page buffer 2170 can include a set of latches, or other types of storage elements, used in read and write (e.g., program and erase) operations and in IMS operations. For memory storage operations, input and output data can be provided through the cache 2190 across lines 2135. The page buffer 2170 can be disposed on an integrated circuit in a manner such that the latches of the page buffer are disposed adjacent to, and operatively connected to, logic circuits for in-memory operations, including in-memory match accumulator logic 2175 that uses one or more latches also used in the memory operations of the memory device to implement an in-memory match accumulator. In some embodiments, the logic circuitry 2175 is disposed at the page buffer and also used for other memory operations, such as selecting a state in a program operation or clearing data after a program verify.

Addresses are supplied on bus 2130 from controller 2110 to page buffer 2170 and word line decoders 2140.

The cache 2190 can be used in the IMS mode for temporarily storing match results, such as stored words passing a similarity match, and metadata about the stored words subject to the IMS operations. Also, logic circuits can be connected to the cache and in the data path between the cache 2190 and the page buffer 2170, to do logic operations using the results of the IMS operations stored in cache.

In the example shown in FIG. 20, controller 2110, using a bias arrangement state machine, controls the application of supply voltages generated or provided through the voltage supply or supplies in block 2120 for IMS operations and for read and write (program and erase) operations in a storage mode.

The controller 2110 can be implemented using special-purpose logic circuitry as known in the art. In alternative embodiments, the control logic comprises a general-purpose processor, which can be implemented on the same integrated circuit, which executes a computer program to control the operations of the device. In yet other embodiments, a combination of special-purpose logic circuitry and a general-purpose processor can be utilized for implementation of the control logic.

Configuration circuitry 2102 can comprise a general-purpose processor, a special purpose processor, a processor configured as a memory controller, or other processor that uses the memory device 2100. All or part of the configuration circuitry 2102 can be implemented on the same integrated circuit as the memory. In example systems, the configuration circuitry 2102 can comprise a digital processing system including a memory controller to interface with the memory system 2100, and may be a system including DRAM and GPU circuits in some examples, for further computations.

The configuration circuitry 2102 can be coupled to other control terminals not shown, such as chip select terminals and so on, and can provide commands or instructions to the system 2100.

The configuration circuitry 2102 can include a file system or file systems that store, retrieve, and update data stored in the memory based on requests from an application program. In general, the configuration circuitry 2102 can include programs that perform memory management functions and other functions that can produce status information for data stored in the memory. Also, the configuration circuitry 2102 can include application programs, file systems, flash translation layer programs and other components that can produce status information for data.

Control logic in the controller 2110 can (i) program the memory device to store storage data according to one or more threshold voltages, (ii) provide one or more search voltages to the memory device in dependence on input data and (iii) determine a level of similarity between the stored storage data and the input data according to an output current from the memory device that represents a Euclidean distance between a stored logical value represented by the stored storage data and an input logical value represented by the input data. Further, the memory controller 2110 can be configured with logic to store one logical value of n logical values as the stored logical value represented by the stored data in each cell of the memory device, n being an integer greater than zero, wherein n has a value ranging from 1 to 15 or even more.

Further, control logic in the configuration circuitry 2102 can determine a base threshold voltage (Vt) according to which the memory controller (i) programs the memory device using one or more programming voltages to set the one or more threshold voltages and (ii) provides the one or more search voltages, wherein the base threshold voltage (Vt) is determined, such that the output current represents the Euclidean distance between the stored logical value represented by the storage data and the input logical value represented by the input data. The logic to determine the base threshold voltage (Vt) can include calculating a partial derivative curve from the known or determined characteristics of the memory device that are represented by the √Id vs gate voltage (Vg) curve and identifying, as the ideal base threshold voltage Vt, a value of the gate voltage (Vg) determined in dependence on a peak point of the calculated partial derivative curve and a line that is tangent to a determined point on the Id vs gate voltage (Vg) curve that corresponds to the peak point, wherein the base threshold voltage (Vt) is set in dependence on the determined ideal base threshold voltage Vt. Further, the logic to determine the base threshold voltage (Vt) can include determining a Vg peak value, which is a voltage that aligns with the peak point of the calculated partial derivative curve, determining the point on the √Id vs gate voltage (Vg) curve that aligns with the determined Vg peak value, calculating the line that is tangent to the determined point on the √Id vs gate voltage (Vg) curve to have a slope defined by the peak point of the calculated partial derivative curve, and determining the ideal base threshold voltage Vt value to correspond to a point on the calculated line where √Id=0. The base threshold voltage (Vt) can be determined in dependence on an extracted base threshold voltage Vt that is calculated by applying the ideal base threshold voltage Vt to a group of memory cells within the memory device, wherein the extracted base threshold voltage Vt is determined by: determining an actual median drain current Id at the determined ideal voltage Vt for a group of memory cells within the memory device and defining the median drain current Id as current Ith; and determining the extracted base threshold voltage Vt from the known drain current Id vs gate voltage (Vg) curve as a voltage on the known drain current Id vs gate voltage (Vg) curve that corresponds to the current Ith, such that the extracted base threshold voltage Vt is an adjusted version of the ideal voltage Vt that is adjusted in dependence on actual varying performance among the group of memory cells. The configuration circuitry 2102 further includes logic to set a ΔV voltage value according to which the base threshold voltage (Vt) is adjusted to store different logical values of the n logical values, wherein the configuration circuitry 2102 includes logic to minimize an error in the Euclidean distance calculated between the stored logical value and the input logical value by defining an adjustment current Iref according to which the output current is divided, such as by an analog current divider.

Other implementations of the method described in this section can include a non-transitory computer readable storage medium storing instructions executable by a processor to perform any of the methods described above. Yet another implementation of the method described in this section can include a system including memory and one or more processors operable to execute instructions, stored in the memory, to perform any of the methods described above.

Any data structures and code described or referenced above are stored according to many implementations on a computer-readable storage medium, which may be any device or medium that can store code and/or data for use by a computer system. This includes, but is not limited to, volatile memory, non-volatile memory, application-specific integrated circuits (ASICs), field-programmable gate arrays (FPGAs), magnetic and optical storage devices such as disk drives, magnetic tape, CDs (compact discs), DVDs (digital versatile discs or digital video discs), or other media capable of storing computer-readable media now known or later developed.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A memory system comprising:
a memory device configured to store data for in-memory searching;
a memory controller configured with logic to (i) program the memory device, according to one or more programming voltages, to store storage data, (ii) provide one or more search voltages to the memory device in dependence on input data and (iii) determine a level of similarity between the stored storage data and the input data according to an output current from the memory device that represents a Euclidean distance between a stored logical value represented by the stored storage data and an input logical value represented by the input data; and
configuration circuitry including logic to determine a base threshold voltage (Vt) according to which the memory controller (i) programs the memory device using the one or more programming voltages to set one or more threshold voltages and (ii) provides the one or more search voltages,
wherein the base threshold voltage (Vt) is determined, such that the output current represents the Euclidean distance between the stored logical value represented by the storage data and the input logical value represented by the input data.

2. The memory system of claim 1, wherein the base threshold voltage (Vt) is determined in dependence on an ideal base threshold voltage Vt that is calculated by extrapolating a line with respect to known or determined characteristics of the memory device that are represented by a √Id vs gate voltage (Vg) curve, where Id is a drain current provided by a memory device in response to the gate voltage (Vg).

3. The memory system of claim 2, wherein the logic to determine the base threshold voltage (Vt) includes:
calculating a partial derivative curve from the known or determined characteristics of the memory device that are represented by the \sqrt{Id} vs gate voltage (Vg) curve; and
identifying, as the ideal base threshold voltage Vt, a value of the gate voltage (Vg) determined in dependence on a peak point of the calculated partial derivative curve and a line that is tangent to a determined point on the \sqrt{Id} vs gate voltage (Vg) curve that corresponds to the peak point,
wherein the base threshold voltage (Vt) is set in dependence on the calculated ideal base threshold voltage Vt.

4. The memory system of claim 3, wherein the logic to determine the base threshold voltage (Vt) further includes:
determining a Vg peak value, which is a voltage that aligns with the peak point of the calculated partial derivative curve;
determining the point on the \sqrt{Id} vs gate voltage (Vg) curve that aligns with the determined Vg peak value;
calculating the line that is tangent to the determined point on the \sqrt{Id} vs gate voltage (Vg) curve to have a slope defined by the peak point of the calculated partial derivative curve; and
determining the ideal base threshold voltage Vt value to correspond to a point on the calculated line where \sqrt{Id}=0.

5. The memory system of claim 2, wherein the base threshold voltage (Vt) is determined in dependence on an extracted base threshold voltage Vt that is calculated by applying the ideal base threshold voltage Vt to a group of memory cells within the memory device.

6. The memory system of claim 5, wherein the extracted base threshold voltage Vt is determined by:
determining an actual median drain current Id at the calculated ideal base threshold voltage Vt for a group of memory cells within the memory device and defining the median drain current Id as current Ith; and
determining the extracted base threshold voltage Vt from the known drain current Id vs gate voltage (Vg) curve as a voltage on the known drain current Id vs gate voltage (Vg) curve that corresponds to the current Ith, such that the extracted base threshold voltage Vt is an adjusted version of the ideal base threshold voltage Vt that is adjusted in dependence on actual varying performance among the group of memory cells.

7. The memory system of claim 1, wherein the memory controller is configured with logic to store one logical value of n logical values as the stored logical value represented by the stored data in each cell of the memory device, n being an integer greater than zero.

8. The memory system of claim 7, wherein n has a value ranging from 1 to 8.

9. The memory system of claim 7, wherein the configuration circuitry further includes logic to set a ΔV voltage value according to which the base threshold voltage (Vt) is adjusted to store different logical values of the n logical values.

10. The memory system according to claim 9, wherein the configuration circuitry includes logic to minimize an error in the Euclidean distance calculated between the stored logical value and the input logical value by defining an adjustment current Iref according to which the output current is divided.

11. The memory system according to claim 10, wherein the adjustment current Iref is calculated in dependence on the set ΔV voltage value, the value of n, and the base threshold voltage (Vt).

12. The memory system of claim 1, wherein the configuration circuitry includes logic to minimize an error in the Euclidean distance calculated between the stored logical value and the input logical value by defining an adjustment current Iref according to which the output current is divided prior to determining the Euclidean distance.

13. The memory system of claim 1, wherein the memory device is a multi-level content addressable memory (MCAM).

14. The memory system of claim 1,
wherein the memory device is a 2D NOR flash memory,
wherein a pair of rows in a particular column in the 2D NOR flash memory is used to store data,
wherein wordlines connected to the pair of rows in the particular column in the 2D NOR flash memory are used to input data which is compared to the stored data, and
wherein one or more data words can be stored in a column of the 2D NOR flash memory.

15. The memory system of claim 14, wherein the 2D NOR flash memory is configured at two-transistor (2T) NOR flash memory and one transistor of each 2T transistor pair is configured to enable or disable searching on a particular row of transistors.

16. The memory system of claim 14, wherein the 2D NOR flash memory is configured as split-gate NOR flash memory and one gate of each transistor is configured to enable or disable searching on a particular row of transistors.

17. The memory system of claim 1, wherein the memory device is a 3D NOR flash memory.

18. A memory device comprising:
memory cells configured to store data for in-memory searching; and
a memory controller configured with logic to:
program the memory device to store storage data according to one or more threshold voltages set in dependence on a base threshold voltage (Vt),
provide one or more search voltages to the memory device in dependence on input data, the one or more search voltages being set in dependence on a base threshold voltage (Vt), and
determine a level of similarity between the stored storage data and the input data according to an output current from the memory device that represents a Euclidean distance between a stored logical value represented by the stored storage data and an input logical value represented by the input data,
wherein the base threshold voltage (Vt) is determined, such that the output current represents the Euclidean distance between the stored logical value represented by the stored storage data and the input logical value represented by the input data.

19. The memory device of claim 18, wherein the base threshold voltage (Vt) is determined in dependence on an ideal base threshold voltage Vt that is calculated by extrapolating a line with respect to known or determined characteristics of the memory device that are represented by a √Id vs gate voltage (Vg) curve, where Id is a drain current provided by a memory device in response to the gate voltage (Vg).

20. The memory device according to claim 19, wherein the logic to determine the base threshold voltage (Vt) includes:
calculating a partial derivative curve from the known or determined characteristics of the memory device that are represented by the \sqrt{Id} vs gate voltage (Vg) curve; and
identifying, as the ideal base threshold voltage Vt, a value of the gate voltage (Vg) determined in dependence on a peak point of the calculated partial derivative curve and a line that is tangent to a determined point on the \sqrt{Id} vs gate voltage (Vg) curve that corresponds to the peak point,
wherein the base threshold voltage (Vt) is set in dependence on the calculated ideal base threshold voltage Vt.
